(19) United States
(12) Patent Application Publication
(10) Pub. No.: US 2024/0290011 A1
(43) Pub. Date: Aug. 29, 2024

(54) DUAL-DOMAIN SELF-SUPERVISED LEARNING FOR ACCELERATED NON-CARTESIAN MAGNETIC RESONANCE IMAGING RECONSTRUCTION

(71) Applicant: Hyperfine, Inc., Guilford, CT (US)

(72) Inventors: Bo Zhou, New Haven, CT (US); Jo Schlemper, Long Island City, NY (US); Neel Dey, Brooklyn, NY (US); Michal Sofka, Princeton, NJ (US)

(73) Assignee: Hyperfine, Inc., Guilford, CT (US)

(21) Appl. No.: 18/597,629

(22) Filed: Mar. 6, 2024

Related U.S. Application Data
(63) Continuation of application No. PCT/US2022/042665, filed on Sep. 6, 2022.
(60) Provisional application No. 63/241,238, filed on Sep. 7, 2021.

(51) Int. Cl. G06T 11/00

(52) U.S. Cl. CPC G06T 11/003

(57) ABSTRACT

Systems and methods for dual-domain self-supervised learning for accelerated non-Cartesian magnetic resonance imaging reconstruction are provided. The present techniques provide a method for training a machine-learning model that receives magnetic resonance (MR) data and generates a reconstruction of the MR data. The machine-learning model can be trained based on a set of losses comprising a first loss value corresponding to a frequency-domain and a second loss value corresponding to an image-based domain. The training process can be a self-supervised training process that can utilize under-sampled and non-Cartesian MR data. The machine-learning model is trained by optimizing both data consistency in the frequency domain and appearance consistency in the image-based domain.

### CROSS-REFERENCE TO RELATED APPLICATIONS

This application claims the benefit of priority under 35 U.S.C. § 120 as a continuation of PCT Patent Application No. PCT/US2022/042665, filed on Sep. 6, 2022, which claims the benefit of and priority to U.S. Provisional Patent Application 63/241,238 filed Sep. 7, 2021, the disclosures of which are incorporated herein by reference in their entirety.

### BACKGROUND

Magnet resonance imaging (MRI) systems can be utilized to generate images of the inside of the human body. MRI systems can be used to detect magnetic resonance (MR) signals in response to applied electromagnetic fields. The MR signals produced by MRI systems may be processed to produce images, which may enable observation of internal anatomy for diagnostic or research purposes. However, it is challenging to accurately reconstruct MR signals captured by MRI systems in an image-based domain, such that anatomical structures are sufficiently observable.

### SUMMARY

At least one aspect of the present disclosure is directed to a method for training a machine-learning model for MR image reconstruction. The method may be performed, for example, by one or more processors coupled to a non-transitory memory. The method may include training a machine-learning model that receives MR data and generates a reconstruction of the MR data. The machine-learning model may be trained based on a set of losses comprising a first loss value corresponding to a frequency-domain and a second loss value corresponding to an image-based domain.

In some implementations, the set of losses can include a partition data consistency (PDC) loss operating in the frequency domain of training data and an appearance consistency (AC) loss operating in the image-based domain of the training data. In some implementations, the AC loss may be computed based on image densities and image gradients. In some implementations, the machine-learning model may be trained based on at least two subsets of training MR data. Each subset may be generated by applying a sampling function to a set of locations of the training data. In some implementations, the two subsets may be disjoint sets.

In some implementations, the machine-learning model may be further trained by feeding the two subsets into a variational network to obtain two predicted subsets. In some implementations, at least one of the losses in the set of losses may be based on the two subsets and the two predicted subsets. In some implementations, the MR data may be MR spatial frequency data captured using an MR system. In some implementations, the MR spatial frequency data may be non-Cartesian. In some implementations, the reconstruction of the MR data comprises a representation of the MR data in the image-based domain.

In some implementations, the machine-learning model may be a generative adversarial network (GAN) model. In some implementations, the first loss value may be calculated based on (1) a first output of the machine-learning model generated using a first subset of input MR data, and (2) a second output of the machine-learning model generated using the input MR data. In some implementations, the first loss value may be calculated further based on a third output of the machine-learning model generated using a second subset of the input MR data. In some implementations, the second loss value may be calculated based on a subset of a transformation of the first output and a corresponding second subset of the input MR data.

In some implementations, the second loss value may be calculated further based on (1) a second transformation of a third output of the machine-learning model generated using the corresponding second subset of the input MR data, and (2) the first subset of the input MR data. In some implementations, the second loss value may be calculated based on a transformation of the first output and the input MR data. In some implementations, the machine-learning model comprises a plurality of convolutional layers and a plurality of data consistency layers. In some implementations, the plurality of convolutional layers and the plurality of data consistency layers may be arranged in a plurality of blocks, such that each of the plurality of blocks comprises at least one convolutional layer and at least one data consistency layer.

In some implementations, the machine-learning model is a dual-domain self-supervised model. In some implementations, the machine-learning model is self-supervised in both k-space and image-based domains. In some implementations, the machine-learning model is a self-supervised model for reconstruction of non-Cartesian MRI data. In some implementations, the method can include receiving patient MR data and feeding the patient MR data to the machine-learning model to obtain a reconstructed image based on the patient MR data. In some implementations, the MR patient data is captured using a low-field MRI scanner.

At least one other aspect of the present disclosure is directed to a method of training a machine-learning model to reconstruct images from MR data. The method can be performed, for example, by one or more processors coupled to a non-transitory memory. The method can include training, based on a first loss value and a second loss value, a machine-learning model that generates MR images from MR spatial frequency data. Training the machine-learning model can include calculating, by the one or more processors, the first loss value based on a first output of the machine-learning model generated using a first partition of input MR spatial frequency data and a second output of the machine-learning model generated using the input MR spatial frequency data. Training the machine-learning model can include calculating the second loss value based on (1) the input MR spatial frequency data and a transformation of the first output of the machine-learning model, or (2) a partition of the transformation of the first output and a second partition of the input MR spatial frequency data.

In some implementations, the method can include generating the first partition of the input MR spatial frequency data by selecting a first subset of the input MR spatial frequency data. In some implementations, the method can include generating the second partition of the input MR spatial frequency data by selecting a second subset of the input MR spatial frequency data. In some implementations, the first partition and the second partition are generated using a sampling function. In some implementations, the partition of the transformation of the first output is generated using the sampling function of the second partition of the input MR spatial frequency data.

In some implementations, the first partition of the input MR spatial frequency data and the second partition of the input MR spatial frequency data are disjoint sets. In some implementations, calculating the first loss value is further based on a third output of the machine-learning model generated using the second partition of the input MR spatial frequency data. In some implementations, calculating the second loss value is further based on a transformation of a third output of the machine-learning model generated using the second partition of the input MR spatial frequency data. In some implementations, the machine-learning model can include a GAN-based model.

In some implementations, the machine-learning model can include a plurality of data consistency layers and a plurality of convolutional layers. In some implementations, the plurality of convolutional layers and the plurality of data consistency layers are arranged in a plurality of blocks, such that each of the plurality of blocks comprises at least one convolutional layer and at least one data consistency layer. In some implementations, the input MR spatial frequency data comprises under-sampled data. In some implementations, the input MR spatial frequency data comprises non-Cartesian sampled data.

In some implementations, the machine-learning model is a dual-domain self-supervised model. In some implementations, the machine-learning model is self-supervised in both k-space and image-based domains. In some implementations, the machine-learning model is a self-supervised model for reconstruction of non-Cartesian MRI data. In some implementations, the method can include receiving patient MR data and feeding the patient MR data to the machine-learning model to obtain a reconstructed image based on the patient MR data. In some implementations, the MR patient data is captured using a low-field MRI scanner.

At least one other aspect of the present disclosure is directed to a system for MR image reconstruction. The system can include an MR imaging system configured to generate MR spatial frequency data. The system can include one or more processors, which may be configured by processor-executable instructions. The system can cause the MR imaging system to generate the MR spatial frequency data based on a non-Cartesian sampling pattern. The system can execute a machine-learning model to generate an MR image based on the MR spatial frequency data. The machine-learning model can be trained based on a first loss value corresponding to a frequency-domain and a second loss value corresponding to an image-based domain.

In some implementations, the machine-learning model is a GAN-based model. In some implementations, the first loss value is calculated based on (1) a first output of the machine-learning model generated using a first subset of MR training data, and (2) a second output of the machine-learning model generated using the MR training data. In some implementations, the first loss value is calculated further based on a third output of the machine-learning model generated using a second subset of the MR training data.

In some implementations, the second loss value is calculated based on a subset of a transformation of the first output and a corresponding second subset of the MR training data. In some implementations, the second loss value is calculated further based on (1) a second transformation of a third output of the machine-learning model generated using the corresponding second subset of the MR training data, and (2) the first subset of the MR training data. In some implementations, the second loss value is calculated based on a transformation of the first output and the MR training data.

In some implementations, the machine-learning model can include a plurality of convolutional layers and a plurality of data consistency layers. In some implementations, the plurality of convolutional layers and the plurality of data consistency layers are arranged in a plurality of blocks, such that each of the plurality of blocks comprises at least one convolutional layer and at least one data consistency layer. In some implementations, the MR imaging system comprises a portable low-field MR imaging device.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification. Aspects can be combined and it will be readily appreciated that features described in the context of one aspect of the present disclosure can be combined with other aspects. Aspects can be implemented in any convenient form. For example, by appropriate computer programs, which may be carried on appropriate carrier media (computer readable media), which may be tangible carrier media (e.g. disks) or intangible carrier media (e.g. communications signals). Aspects may also be implemented using suitable apparatus, which may take the form of programmable computers running computer programs arranged to implement the aspect. As used in the specification and in the claims, the singular form of “a,” “an,” and “the” include plural referents unless the context clearly dictates otherwise.

### BRIEF DESCRIPTION OF THE DRAWINGS

The accompanying drawings are not intended to be drawn to scale. Like reference numbers and designations in the various drawings indicate like elements. For purposes of clarity, not every component may be labeled in every drawing. In the drawings:

FIG. 1A illustrates example components of a magnetic resonance imaging system, in accordance with one or more implementations;

FIG. 1B illustrates an example system for training and utilizing machine-learning models for MR image reconstruction using dual-domain self-supervised learning techniques, in accordance with one or more implementations;

FIG. 2A depicts a diagram of an example architecture of a machine-learning model for generating MR images from input MR spatial frequency data, in accordance with one or more implementations;

FIG. 2B depicts a diagram of an example architecture of a data consistency block, which may be part of the example architecture shown in FIG. 2A, in accordance with one or more implementations;

FIG. 2C depicts a diagram of an example architecture of a convolutional neural network block, which may be part of the example architecture shown in FIG. 2A, in accordance with one or more implementations;

FIG. 3 depicts an example dataflow diagram of a dual-domain self-supervised learning process that may be utilized to train a machine-learning model to generate reconstructed MR images, in accordance with one or more implementations;

FIG. 4 illustrates a flowchart of an example method of training a machine-learning model to generate reconstructed MR images using dual-domain self-supervised learning techniques, in accordance with one or more implementations;

FIG. 5 depicts visualizations of example non-Cartesian MRI reconstructions using supervised, single-domain self-supervised (KDSS), and dual-domain self-supervised (DDSS) approaches, in accordance with one or more implementations;

FIG. 6 depicts visualizations of a qualitative evaluation of FSE-T2w and FLAIR reconstructions from data acquired from a low-field (64 mT) MRI system, in accordance with one or more implementations;

FIGS. 7A and 7B depict the impact of the number of iterations in the non-Cartesian reconstruction network for Dual-Domain Self-Supervised (DDSS) reconstruction, in accordance with one or more implementations;

FIG. 8 depicts visualizations of MR image reconstructions of FSE-T2w and FLAIR using a fully supervised model and a DDSS model trained on simulation data, in accordance with one or more implementations;

FIG. 9 depicts a visualization of a qualitative comparison of the present DDSS techniques with an alternative backbone reconstruction network approach, in accordance with one or more implementations;

FIG. 10 depicts an example dataflow diagram of an alternative dual-domain self-supervised learning process that may be utilized to train a machine-learning model to generate reconstructed MR images, in accordance with one or more implementations;

FIG. 11 illustrates a flowchart of an example method of training a machine-learning model to generate reconstructed MR images using alternative dual-domain self-supervised learning techniques, in accordance with one or more implementations;

FIG. 12 illustrates an example visual comparison of MR image reconstruction using conventional methods and the dual-domain self-supervised techniques described herein with a simulation dataset, in accordance with one or more implementations;

FIG. 13 illustrates another example visual comparison of MR image reconstruction using conventional methods and the dual-domain self-supervised techniques described herein with a simulation dataset, in accordance with one or more implementations;

FIG. 14 illustrates visualizations of FSE-T2 and FLAIR reconstructions from real clinical data, in accordance with one or more implementations;

FIG. 15 illustrates additional visualizations of FSE-T2 and FLAIR reconstructions from real clinical data, in accordance with one or more implementations;

FIG. 16 illustrates graphs indicating results of a reader study performed on reconstructions generated using the techniques described herein and alternative approaches, in accordance with one or more implementations; and

FIG. 17 is a block diagram of an example computing system suitable for use in the various arrangements described herein, in accordance with one or more example implementations.

### DETAILED DESCRIPTION

Magnet resonance imaging (MRI) systems generate images for health evaluation. MRI images are generated by “scanning” a patient while the MRI system applies magnetic fields to the patient and particular data is captured. MRI scans produce raw scan data that can be transformed or otherwise processed into an image that can then be analyzed or reviewed to better evaluate a patient's health. MRI scans that take longer generally can capture more raw data that may be used to produce images, while faster MRI scans, which require patients to be in an MRI system for significantly less time, can produce images from less raw scan data. To allow for faster scans with high image quality, the MRI data is processed differently.

Machine-learning can be used to teach a computer to perform tasks, such as transforming raw scan data into images, without having to specifically program the computer to perform those tasks. This is especially useful when, for example, images are to be constructed from fast raw scan data that can vary greatly from one patient to the next. This provides a machine-learning model that has learned to perform the particular task, but the effectiveness of the model in different situations can vary greatly depending on how the model was trained. Often, machine-learning approaches train a model by showing the model what a specific output (result) should be provided by the model when the model receives certain input. That is, to train machine-learning model to generate images from raw MRI scan data, the output that is desired from particular raw MRI scan data are “shown” to the model so the model can learn what images should be produced from such raw MRI scan data.

However, this requires that such “desired” images be available for use to train the machine learning model. Hypothetically, such data may be obtainable, for example, by having a large number of patients (e.g., hundreds of patients) each simultaneously undergo both fast scans and slow scans, and the raw data from the fast scans can be paired with the images resulting from the slow scans so the model can learn how images from fast scans would look had they been captured using slow scans. This is very costly and impractical, and this disclosure provides for an effective and efficient alternative without requiring such extensive training data. The approaches described herein can provide machine-learning models that are trained using scan data from faster MRI machines (without requiring scan data from slower scans). This can be accomplished by allowing the machine-learning model to learn from the raw data itself, in combination with the images that are generated from the raw data. As discussed in more detail below, machine-learning models can effectively learn to “fill in the gaps” by learning from subsets (“partitions”) of scan data, in both raw form and in an image-based form, without the need for more extensive scan data.

Below are detailed descriptions of various concepts related to and implementations of techniques, approaches, methods, apparatuses, and systems for dual-domain self-supervised learning for accelerated non-Cartesian magnetic resonance imaging reconstruction. The various concepts introduced above and discussed in detail below may be implemented in any of numerous ways, as the described concepts are not limited to any particular manner of implementation. Examples of specific implementations and applications are provided primarily for illustrative purposes.

MRI is a common medical imaging modality for disease diagnosis. However, MRI is inherently challenging due to its slow acquisition arising from physical and physiological constraints. For example, conventional MRI techniques require time-consuming scans (e.g., scan times ranging from 15 minutes to over an hour depending on the protocol) to obtain high-resolution images of the patient's anatomy. Prolonged MR imaging sessions are impractical as they lead to increased patient discomfort and increased accumulation of motion artifacts and system imperfections in the image. The use of accelerated MRI systems is one approach to solving these issues. However, accelerated MRI systems have some limitations.

Data points captured using accelerated MRI systems include data points in the spatial frequency domain (sometimes referred to herein as “k-space” data). In Cartesian MRI systems, a k-space grid can be uniformly sampled and an inverse Fourier transform may be directly applied to reconstruct the image (assuming that the Nyquist sampling rate is met). However, accelerated or rapid MRI systems can utilize non-uniform or non-Cartesian sampling patterns, such as spiral, radial, variable density, and optimized sampling patterns. These non-Cartesian sampling patterns offer a number of advantages, including more efficient coverage of k-space and enhanced robustness against patient motion. However, such rapid scans generally result in fewer data points from which the MRI image can be reconstructed when compared to conventional MRI systems. As used herein, “non-uniform” indicates that sampled k-spaced points are non-equidistant. As used herein, “non-Cartesian” indicates that sampled k-space points are off the Cartesian grid, and can be uniform or non-uniform.

When fewer data points are obtained than required by the spatial Nyquist criteria (referred to herein as “under-sampled” k-space data), the MR image generated from the collected data points by an inverse Fourier transform may include artifacts or inconsistencies. These artifacts can degrade image quality interpretability, making such approaches less than desirable without additional reconstruction processing. Machine-learning techniques, including deep learning, can be used to reconstruct MR images from under-sampled k-space data. Conventional deep-learning approaches utilize a machine-learning model, such as a neural network, that is trained using uniformly and fully sampled data (e.g., data satisfying the spatial Nyquist criteria) as training data in a supervised learning process. However, fully sampled MRI is prohibitively time-consuming to acquire, and non-Cartesian sampling patterns are particularly desirable as they are more amenable to acceleration and show improved motion robustness. In addition, non-Cartesian sampling can be better suited to compressed sensing (CS) and deep learning (DL) reconstruction techniques, as aliasing artifacts from non-Cartesian sampling can show higher noise-like incoherence than uniform sampling.

Two MR image reconstruction techniques include CS-based reconstruction and DL-based reconstruction. CS-based reconstruction methods can use sparse coefficients in transform-domains (e.g. wavelets, etc.) with application-specific regularizers (e.g. total variation) to solve the ill-posed inverse problem in an iterative fashion. However, iterative sparse optimization approaches are prone to reconstructing over-smoothed anatomical structures and can result in undesirable image artifacts, especially when the acceleration factor is high (e.g., when the acceleration factor is greater than 3). Moreover, iterative optimization-based reconstruction is time-consuming, requires careful parameter tuning across different scanners and protocols, and may require subject-specific tuning.

Conventional DL-based reconstruction methods have demonstrated improvements over CS-based methods, but often rely on large-scale MRI datasets. In addition, conventional DL-based reconstruction methods are limited to uniform sampling patterns and are supervised, thus requiring paired fully sampled acquisitions for supervised learning. These requirements are impractical because real-world MRI use-cases may not have the time or resources to fully sample k-space for supervised training, or may prefer non-Cartesian sampling for its motion robustness advantages, among others. For example, full dense k-space sampling may be impossible for real-time cardiac MRI and functional brain MRI where data acquisition periods are restricted.

Various DL-based MR reconstruction approaches include training a three-layer convolutional network to map accelerated zero-filled reconstructions to fully sampled reconstructions, an iterative optimization procedures to train deep reconstruction networks, utilizing a deep cascade network with data consistency layers to approximate the closed-form solution of the iterative reconstruction, using such deep cascade networks with recurrent components, unrolling iterative optimization steps into a variational network, adversarial learning techniques, aggregating the spatial-frequency context with a dual-octave convolution network, restoring missing k-space measurements with deep models, learning mappings between under-sampled k-space measurements to an image-based domain, and using multi-modal MRI input into reconstruction networks. Example image-based domains may include image gradient, image feature space, wavelet domain, etc.

However, the aforementioned DL-based techniques perform MRI reconstruction while requiring uniform sampling patterns. Some approaches to addressing non-Cartesian sampling patterns include training a variational network with a conjugate gradient-based data consistency blocks, and using gradient descent-based variational networks. However, such techniques require supervised training from largescale paired non-Cartesian MRI, which is impracticable to obtain in real-world scanners.

One approach used to obviate the need for supervised training and fully sampled data includes self-supervised learning techniques to train reconstruction models. Self-supervised reconstruction approaches can be utilized to train models using under-sampled non-Cartesian data. However, conventional self-supervised learning techniques are limited to uniform MRI sampling patterns and fail to perform self-supervised learning for accelerated non-Cartesian MRI reconstruction. Such techniques also rely entirely on k-space data and thus do not implement self-supervised learning in the image-based domain.

The techniques described herein address these and other issues by providing a fully self-supervised approach for accelerated non-Cartesian MRI reconstruction, which leverages self-supervision in both k-space and image-based domains. Combining image and k-space domains in dual-domain learning can further improve reconstruction as compared to learning reconstruction in a single domain only. In training, under-sampled data can be split into disjoint k-space domain partitions. The k-space self-supervision techniques include predicting one partition using the other partition, and vice-versa. The image-based domain self-supervision techniques include enforcing the consistency between the partition reconstructions and the original under-sampled reconstruction. Experimental results of the techniques described herein on an example non-Cartesian MRI dataset demonstrate that the DDSS can generate accurate reconstruction that approaches the accuracy of the fully supervised reconstruction, without needing to rely on fully-sampled datasets. The techniques described herein can be scaled to challenging clinical MRI reconstruction acquired on portable low-field (e.g., that is less than about 0.5 T, that is less than about 0.2 T, that is between about 100 mT and about 400 mT, that is between about 200 mT and about 300 mT, that is between about 1 mT and 100 mT, that is between about 50 mT and about 100 mT, that is between about 40 and about 80 mT, that is about 64 mT, etc.) MRI systems with no data available for supervised training, while demonstrating improved perceptual quality as compared to traditional reconstruction approaches. The advantages of the techniques described herein include a self-supervised learning approach that enables training deep networks for non-Cartesian MRI reconstruction without access to fully sampled data and self-supervised reconstruction in both k-space and image-based domains. The systems and methods described herein therefore provide technical improvements over conventional MRI image reconstruction approaches.

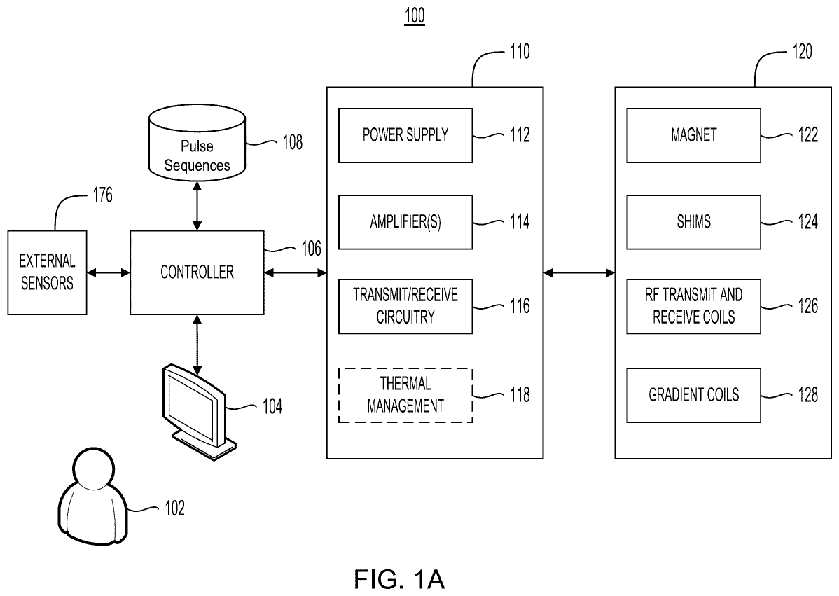

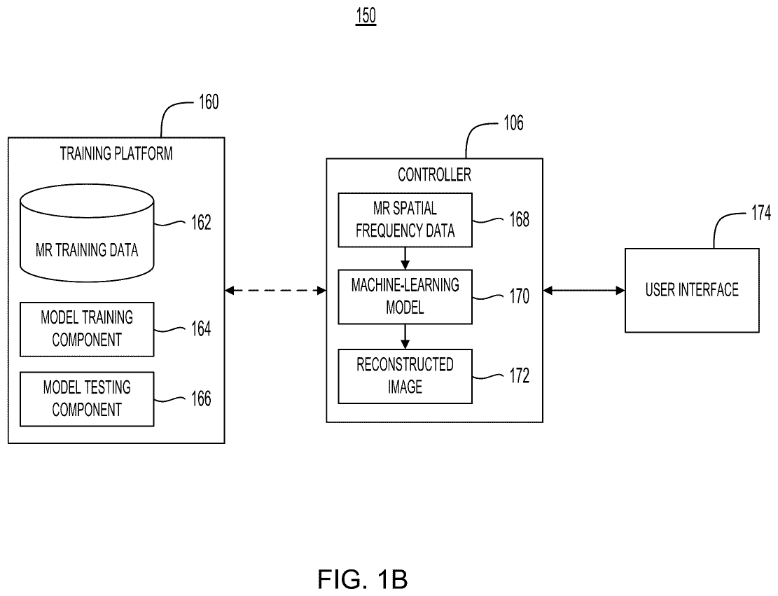

The DDSS techniques can be utilized to train machine-learning reconstruction models that can be executed by MRI systems, including portable MRI systems. FIG. 1A illustrates an example MRI system which may be used with the reconstruction models trained using the DDSS techniques described herein. In FIG. 1A, MRI system 100 can include a computing device 104, a controller 106, a pulse sequences repository 108, a power management system 110, and magnetics components 120. The MRI system 100 is illustrative, and an MRI system may have one or more other components of any suitable type in addition to or instead of the components illustrated in FIG. 1A. Additionally, the implementation of components for a particular MRI system may differ from those described herein. Examples of low-field MRI systems may include portable MRI systems, which may have a field strength that is, for example, less than or equal to 0.5 T, that is less than or equal to 0.2 T, that is within a range from 1 mT to 100 mT, that is within a range from 50 mT to 0.1 T, that is within a range of 40 mT to 80 mT, that is about 64 mT, etc.

The magnetics components 120 can include Bo magnets 122, shims 124, radio frequency (RF) transmit and receive coils 126, and gradient coils 128. The Bo magnets 122 may be used to generate a main magnetic field Bo. Bo magnets 122 may be any suitable type or combination of magnetics components that can generate a desired main magnetic Bo field. In some embodiments, Bo magnets 122 may be one or more permanent magnets, one or more electromagnets, one or more superconducting magnets, or a hybrid magnet comprising one or more permanent magnets and one or more electromagnets or one or more superconducting magnets. In some embodiments, Bo magnets 122 may be configured to generate a Bo magnetic field having a field strength that is less than or equal to 0.2 T or within a range from 50 mT to 0.1 T.

In some implementations, the Bo magnets 122 may include a first and second Bo magnet, which may each include permanent magnet blocks arranged in concentric rings about a common center. The first and second Bo magnet may be arranged in a bi-planar configuration such that the imaging region is located between the first and second Bo magnets. In some embodiments, the first and second Bo magnets may each be coupled to and supported by a ferromagnetic yoke configured to capture and direct magnetic flux from the first and second Bo magnets.

The gradient coils 128 may be arranged to provide gradient fields and, for example, may be arranged to generate gradients in the BO field in three substantially orthogonal directions (X, Y, and Z). Gradient coils 128 may be configured to encode emitted MR signals by systematically varying the Bo field (the Bo field generated by the Bo magnets 122 or shims 124) to encode the spatial location of received MR signals as a function of frequency or phase. For example, the gradient coils 128 may be configured to vary frequency or phase as a linear function of spatial location along a particular direction, although more complex spatial encoding profiles may also be provided by using nonlinear gradient coils. In some embodiments, the gradient coils 128 may be implemented using laminate panels (e.g., printed circuit boards), for example.

MRI scans are performed by exciting and detecting emitted MR signals using transmit and receive coils, respectively (referred to herein as radio frequency (RF) coils). The transmit and receive coils may include separate coils for transmitting and receiving, multiple coils for transmitting or receiving, or the same coils for transmitting and receiving. Thus, a transmit/receive component may include one or more coils for transmitting, one or more coils for receiving, or one or more coils for transmitting and receiving. The transmit/receive coils can be referred to as Tx/Rx or Tx/Rx coils to generically refer to the various configurations for transmit and receive magnetics components of an MRI system. These terms are used interchangeably herein. In FIG. 1A, RF transmit and receive coils 126 can include one or more transmit coils that may be used to generate RF pulses to induce an oscillating magnetic field B₁. The transmit coil(s) may be configured to generate any type of suitable RF pulses.

The power management system 110 includes electronics to provide operating power to one or more components of the MRI system 100. For example, the power management system 110 may include one or more power supplies, energy storage devices, gradient power components, transmit coil components, or any other suitable power electronics needed to provide suitable operating power to energize and operate components of MRI system 100. As illustrated in FIG. 1A, the power management system 110 can include a power supply system 112, power component(s) 114, transmit/receive circuitry 116, and may optionally include thermal management components 118 (e.g., cryogenic cooling equipment for superconducting magnets, water cooling equipment for electromagnets).

The power supply system 112 can include electronics that provide operating power to magnetic components 120 of the MRI system 100. The electronics of the power supply system 112 may provide, for example, operating power to one or more gradient coils (e.g., gradient coils 128) to generate one or more gradient magnetic fields to provide spatial encoding of the MR signals. Additionally, the electronics of the power supply system 112 may provide operating power to one or more RF coils (e.g., RF transmit and receive coils 126) to generate or receive one or more RF signals from the subject. For example, the power supply system 112 may include a power supply configured to provide power from mains electricity to the MRI system or an energy storage device. The power supply may, in some embodiments, be an AC-to-DC power supply that converts AC power from mains electricity into DC power for use by the MRI system. The energy storage device may, in some embodiments, be any one of a battery, a capacitor, an ultracapacitor, a flywheel, or any other suitable energy storage apparatus that may bi-directionally receive (e.g., store) power from mains electricity and supply power to the MRI system. Additionally, the power supply system 112 may include additional power electronics including, but not limited to, power converters, switches, buses, drivers, and any other suitable electronics for supplying the MRI system with power.

The amplifiers(s) 114 may include one or more RF receive (Rx) pre-amplifiers that amplify MR signals detected by one or more RF receive coils (e.g., coils 126), one or more RF transmit (Tx) power components configured to provide power to one or more RF transmit coils (e.g., coils 126), one or more gradient power components configured to provide power to one or more gradient coils (e.g., gradient coils 128), and may provide power to one or more shim power components configured to provide power to one or more shims (e.g., shims 124). In some implementations, the shims 124 may be implemented using permanent magnets, electromagnetics (e.g., a coil), or combinations thereof. The transmit/receive circuitry 116 may be used to select whether RF transmit coils or RF receive coils are being operated.

As illustrated in FIG. 1A, the MRI system 100 can include the controller 106 (also referred to as a console), which can include control electronics to send instructions to and receive information from power management system 110. The controller 106 may be configured to implement one or more pulse sequences, which are used to determine the instructions sent to power management system 110 to operate the magnetic components 120 in a desired sequence (e.g., parameters for operating the RF transmit and receive coils 126, parameters for operating gradient coils 128, etc.). A pulse sequence may generally describe the order and timing in which the RF transmit and receive coils 126 and the gradient coils 128 operate to acquire resulting MR data. For example, a pulse sequence may indicate an order and duration of transmit pulses, gradient pulses, and acquisition times during which the receive coils acquire MR data.

A pulse sequence may be organized into a series of periods. For example, a pulse sequence may include a pre-programmed number of pulse repetition periods, and applying a pulse sequence may include operating the MRI system in accordance with parameters of the pulse sequence for the pre-programmed number of pulse repetition periods. In each period, the pulse sequence may include parameters for generating RF pulses (e.g., parameters identifying transmit duration, waveform, amplitude, phase, etc.), parameters for generating gradient fields (e.g., parameters identifying transmit duration, waveform, amplitude, phase, etc.), timing parameters governing when RF or gradient pulses are generated or when the receive coil(s) are configured to detect MR signals generated by the subject, among other functionality. In some embodiments, a pulse sequence may include parameters specifying one or more navigator RF pulses, as described herein.

Examples of pulse sequences include zero echo time (ZTE) pulse sequences, balance steady-state free precession (bSSFP) pulse sequences, gradient echo pulse sequences, inversion recovery pulse sequences, diffusion weighted imaging (DWI) pulse sequences, spin echo pulse sequences including conventional spin echo (CSE) pulse sequences, fast spin echo (FSE) pulse sequences, turbo spin echo (TSE) pulse sequences or any multi-spin echo pulse sequences such a diffusion weighted spin echo pulse sequences, inversion recovery spin echo pulse sequences, arterial spin labeling pulse sequences, and Overhauser imaging pulse sequences, among others.

As illustrated in FIG. 1A, the controller 106 can communicate with the computing device 104, which can be programmed to process received MR data. For example, the computing device 104 may process received MR data to generate one or more MR images using any suitable image reconstruction processes, including the execution of machine-learning models trained using the DDSS techniques described herein. Additionally or alternatively, the controller 106 can process received MR data to generate one or more MR images using any suitable image reconstruction processes, including the execution of machine-learning models trained using the DDSS techniques described herein. The controller 106 may provide information about one or more pulse sequences to computing device 104 for the processing of data by the computing device. For example, the controller 106 may provide information about one or more pulse sequences to the computing device 104 and the computing device may perform an image reconstruction process based, at least in part, on the provided information.

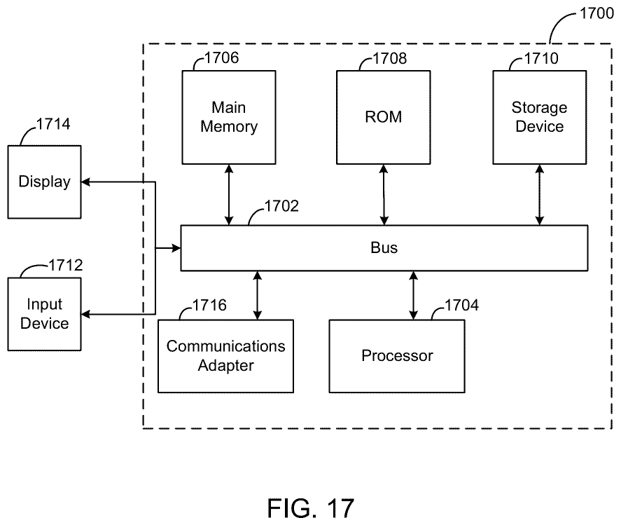

The computing device 104 can be any electronic device configured to process acquired MR data and generate one or more images of a subject being imaged. The computing device 104 can include at least one processor and a memory (e.g., a processing circuit). The memory can store processor-executable instructions that, when executed by a processor, cause the processor to perform one or more of the operations described herein. The processor may include a microprocessor, an application-specific integrated circuit (ASIC), a field-programmable gate array (FPGA), a graphics processing unit (GPU), a tensor processing unity (TPU), etc., or combinations thereof. The memory may include, but is not limited to, electronic, optical, magnetic, or any other storage or transmission device capable of providing the processor with program instructions. The memory may further include a floppy disk, CD-ROM, DVD, magnetic disk, memory chip, ASIC, FPGA, read-only memory (ROM), random-access memory (RAM), electrically erasable programmable ROM (EEPROM), erasable programmable ROM (EPROM), flash memory, optical media, or any other suitable memory from which the processor can read instructions. The instructions may include code generated from any suitable computer programming language. The computing device 104 can include any or all of the components and perform any or all of the functions of the computer system 1700 described in connection with FIG. 17. In some implementations, the computing device 104 may be located in a same room as the MRI system 100 or coupled to the MRI system 100 via wired or wireless connection.

In some implementations, computing device 104 may be a fixed electronic device such as a desktop computer, a server, a rack-mounted computer, or any other suitable fixed electronic device that may be configured to process MR data and generate one or more images of the subject being imaged. Alternatively, computing device 104 may be a portable device such as a smart phone, a personal digital assistant, a laptop computer, a tablet computer, or any other portable device that may be configured to process MR data and generate one or images of the subject being imaged. In some implementations, computing device 104 may comprise multiple computing devices of any suitable type, as aspects of the disclosure provided herein are not limited in this respect. In some implementations, operations that are described as being performed by the computing device 104 may instead be performed by the controller 106, or vice-versa. In some implementations, certain operations may be performed by both the controller 106 and the computing device 104 via communications between said devices.

The MRI system 100 may include one or more external sensors 176. The one or more external sensors may assist in detecting one or more error sources (e.g., motion, noise) which degrade image quality. The controller 106 may be configured to receive information from the one or more external sensors 176. In some embodiments, the controller 106 of the MRI system 100 may be configured to control operations of the one or more external sensors 176, as well as collect information from the one or more external sensors 176. The data collected from the one or more external sensors 176 may be stored in a suitable computer memory and may be utilized to assist with various processing operations of the MRI system 100.

As described herein above, the techniques described herein implement a fully self-supervised approach for accelerated non-Cartesian MRI reconstruction, which leverages self-supervision in both k-space and image-based domains. Combining image and k-space domains in dual-domain learning further improves reconstruction accuracy as compared to learning reconstruction in a single-domain only. This enables the training of machine-learning models that approach the accuracy of models trained using supervised techniques, but without requiring large fully sampled datasets. The training processes described herein produce accurate models using under-sampled and non-Cartesian MR data, which is an improvement over other techniques.

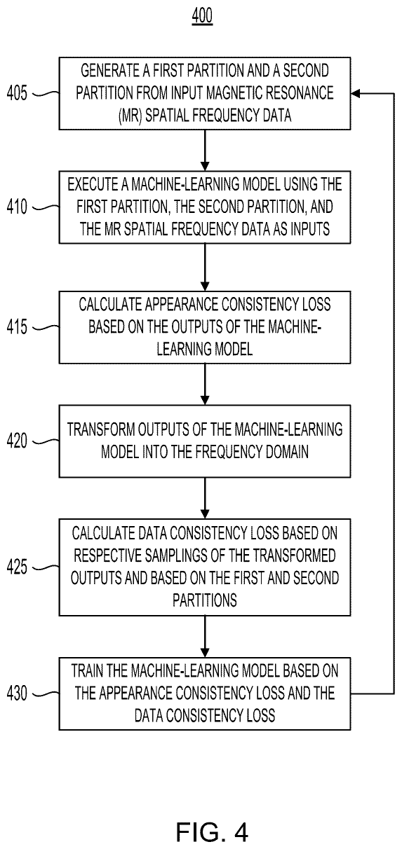

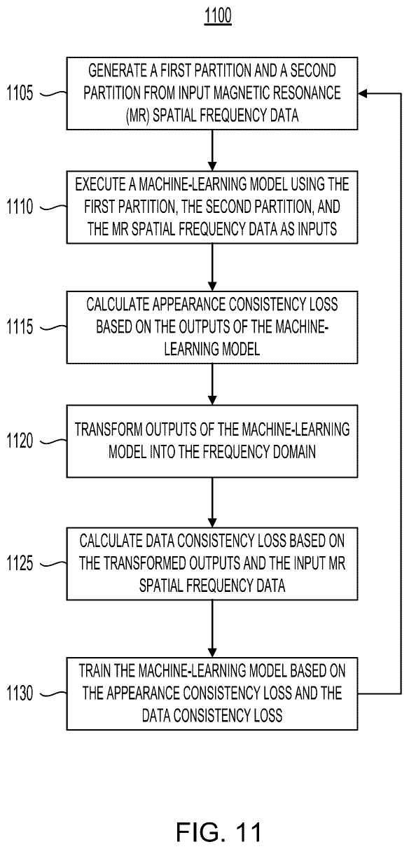

FIG. 1B illustrates an example system 150 for training and utilizing machine-learning models for MR image reconstruction using DDSS techniques, in accordance with one or more implementations. For example, the system 150 may be used to perform all or part of the example method 400 described in connection with FIG. 4 or all or part of the example method 1100 described in connection with FIG. 11, as well as any other operations described herein. In some implementations, the system 150 forms a portion of an MRI system, such as MRI system 100 described in connection with FIG. 1A. In some implementations, the system 150 is external to an MRI system but communicates with the MRI system (or components thereof) to perform the example method 400 or the method 1100 as described herein.

As shown in FIG. 1B, the example system 150 can include the controller 106, a training platform 160, and a user interface 174. The user interface 174 can present or enable inspection of any of the reconstructed MR images generated using the techniques described herein. The user interface 174 can provide input relating to the performance such techniques, for example, by receiving input or configuration data relating to the training process, MR scans, or MR image reconstruction. The user interface 174 may allow a user to select a type of imaging to be performed by the MRI system (e.g., diffusion-weighted imaging, etc.), select a sampling density for the MR scan, or to define any other type of parameter relating to MR imaging or model training as described herein. In some implementations, the user interface 174 may display, via a display in communication with the user interface 174, reconstructed images generated from MR data acquired by the MRI system. The user interface 174 may allow a user to initiate imaging by the MRI system.

The controller 106 can control aspects of the example system 150, for example to perform at least a portion of the example method 400 described in connection with FIG. 4 or the example method 1100 described in connection with FIG. 11, as well as any other operations described herein. In some implementations, the controller 106 can control one or more operations of the MRI system, such as the MRI system 100 described in connection with FIG. 1A. Additionally or alternatively, the computing device 104 of FIG. 1A may perform some or all of the functionality of the controller 106. In such implementations, the computing device 104 can be in communication with the controller 106 to exchange information as necessary to achieve desired results.

The controller 106 may be implemented using software, hardware, or a combination thereof. The controller 106 can include at least one processor and a memory (e.g., a processing circuit). The memory can store processor-executable instructions that, when executed by a processor, cause the processor to perform one or more of the operations described herein. The processor may include a microprocessor, an ASIC, an FPGA, a GPU, a TPU, etc., or combinations thereof. The memory may include, but is not limited to, electronic, optical, magnetic, or any other storage or transmission device capable of providing the processor with program instructions. The memory may further include a floppy disk, CD-ROM, DVD, magnetic disk, memory chip, ASIC, FPGA, ROM, RAM, EEPROM, EPROM, flash memory, optical media, or any other suitable memory from which the processor can read instructions. The instructions may include code generated from any suitable computer programming language. The controller 106 can include any or all of the components and perform any or all of the functions of the computer system 1700 described in connection with FIG. 17.

The controller 106 may be configured to perform one or more functions described herein. The controller 106 can store or capture MR spatial frequency data 168. The MR spatial frequency data 168 can be obtained using an MR system, such as the MR system 100 described in connection with FIG. 1A. In some implementations, the MR spatial frequency data 168 can be obtained externally and provided to the controller 106 via one or more communication interfaces. The MR spatial frequency data 168 can be under-sampled relative to the Nyquist sampling criterion. For example, in some embodiments, the spatial frequency domain data may include less than 90% (or less than 80%, or less than 75%, or less than 70%, or less than 65%, or less than 60%, or less than 55%, or less than 50%, or less than 40%, or less than 35%, or any percentage between 25 and 100) of the number of data samples required by the Nyquist criterion. Similarly, the MR spatial frequency data 168 may be non-Cartesian data. The MR spatial frequency data 168 may be represented in the k-space domain, as described herein. The MR spatial frequency data 168 may be generated by an MR scanner, which may utilize a suitable pulse sequence and sampling technique. In some implementations, the MR spatial frequency data 168 may be gathered using a Cartesian sampling scheme. Alternatively, MR spatial frequency data 168 may be generated using a non-Cartesian sampling scheme, such as a radial, spiral, rosette, or Lissajou sampling scheme, among others.

The controller 106 may include a machine-learning model 170. The machine-learning model 170 may be similar to, or may include, any of the reconstruction models described herein. The machine-learning model 170 may be or may include a variational reconstruction network, as described herein. The controller 106 can execute the machine-learning model 170 using the MR spatial frequency data 168 as input to generate a reconstructed image 172. The machine-learning model 170 can be trained by the model training component 164 of the training platform, for example, by implementing the example method 400 of FIG. 4 or the example method 1100 of FIG. 11. As described in further detail herein, the machine-learning model 170 can generate the reconstructed image 172 from the MR spatial frequency data 168. The reconstructed image 172 generated by the machine-learning model 170 can be presented, for example, for inspection by a user at the user interface 174. The reconstructed image 172, upon generation, may be stored in one or more data structures in the memory of the controller 106.

The training platform 160 may be, or may include, the computing device 104 of FIG. 1A. Alternatively, the training platform 160 (or any components thereof) may be implemented as part of the controller 106. The training platform 160 can include at least one processor and a memory (e.g., a processing circuit). The memory can store processor-executable instructions that, when executed by a processor, cause the processor to perform one or more of the operations described herein. The processor may include a microprocessor, an ASIC, an FPGA, a GPU, a TPU, etc., or combinations thereof. The memory may include, but is not limited to, electronic, optical, magnetic, or any other storage or transmission device capable of providing the processor with program instructions. The memory may further include a floppy disk, CD-ROM, DVD, magnetic disk, memory chip, ASIC, FPGA, ROM, RAM, EEPROM, EPROM, flash memory, optical media, or any other suitable memory from which the processor can read instructions. The instructions may include code generated from any suitable computer programming language. The training platform 160 can include any or all of the components and perform any or all of the functions of the computer system 1700 described in connection with FIG. 17. In some implementations, the training platform 160 can be a desktop computer, a server, a rack-mounted computer, a distributed computing environment, or any other computing system that may be configured to train the machine-learning model 170 sign the DDSS training techniques described herein. The training platform 160 can include any number of computing devices of any suitable type.

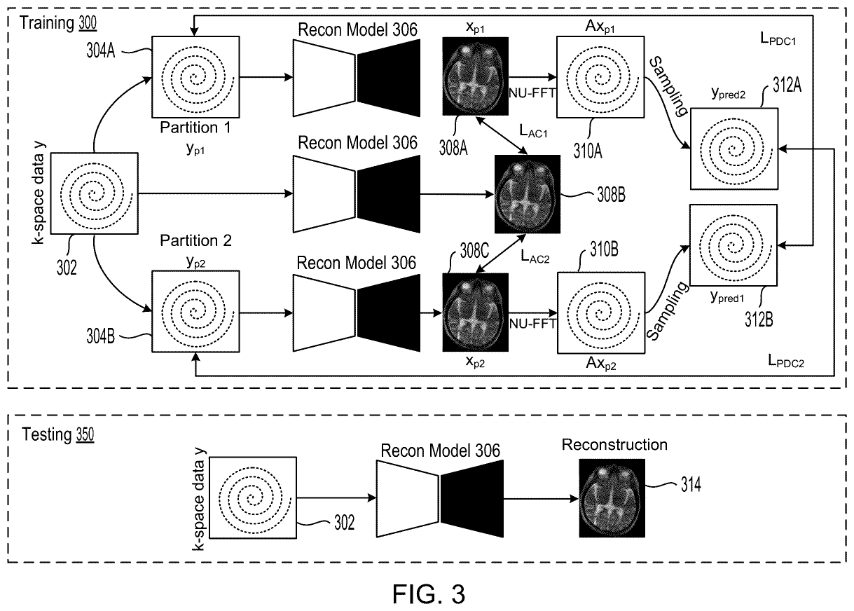

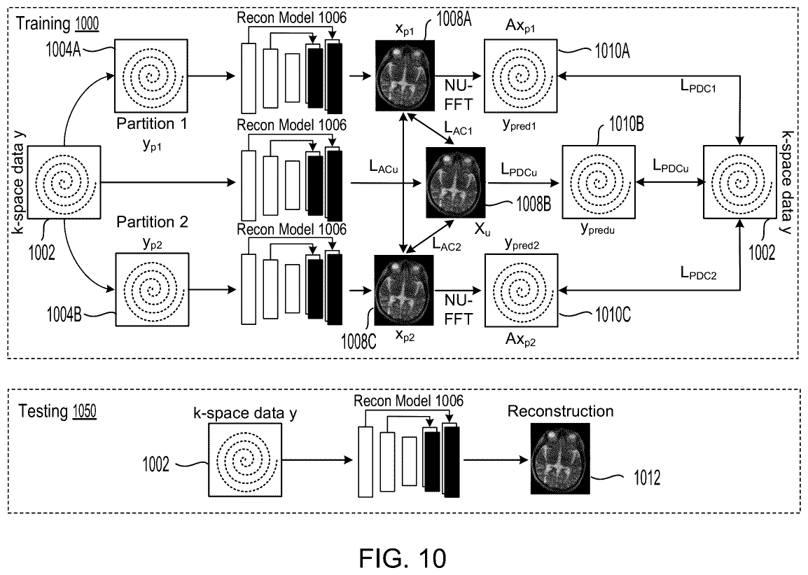

The training platform 160 can include a MR training data repository 162, a model training component 164, and a model testing component 166. The model training component 164 and the model testing component 166 may be implemented using any suitable combination of software or hardware. Additionally or alternatively, the model training component 164 and the model testing component 166 may be implemented by one or more servers or distributed computing systems, which may include a cloud computing system. In some implementations, the model training component 164 and the model testing component 166 may be implemented using one or more virtual servers or computing systems. The model training component 164 can implement the example method 400 described in connection with FIG. 4 or the example method 1100 described in connection with FIG. 11 to train the machine-learning model 170, as well as any other operations relating to the training of a reconstruction model as described herein. These training processes may be similar to the training process 300 described in connection with FIG. 3 or the training process 1000 described in connection with FIG. 10, each of which may be implemented by the model training component 164 to train the machine-learning model 170.

The model training component 164 can utilize the training data in the MR training data repository 162 to train the machine-learning model 170. The MR training data repository 162 can store batches of MR spatial frequency data that can be utilized to train the machine-learning model 170 using the DDSS techniques described herein. The MR spatial frequency data in the MR training data repository 162 can be previously generated by an MR scanner (e.g., include multiple historic MRI scans). The MR spatial frequency data in the MR training data repository 162 can represented in the k-space domain, and may have been generated using a non-Cartesian sampling scheme, such as a radial, spiral, rosette, or Lissajou sampling scheme, among others. The spatial frequency data in the MR training data repository 162 may be augmented, for example, by applying affine transformations to create images with different orientation and size, by adding noise to create images with different SNR, introducing motion artifacts, incorporating phase or signal modulation for more complex sequences like echo trains, or modeling the dephasing of the data to adapt the model to a sequence-like diffusion weighted imaging.

The MR spatial frequency data in the MR training data repository 162 may include non-Cartesian and under-sampled k-space data. The model training component 164 may perform any of the functionality relating to the DDSS techniques described herein to train the machine-learning model 170. Once the machine-learning model 170 has been trained (e.g., the training process has terminated), the training platform 160 can provide the trained machine-learning model 170 to the controller 106, such that the controller can use the machine-learning model 170 to generate reconstructed images 172, as described herein.

The training platform 160 can include a model testing component 166, which may be configured to test the machine-learning model 170 prior to deployment at the controller 106. For example, during training, the model testing component 166 can perform one or more testing processes (e.g., the testing process 350 described in connection with FIG. 3 or the testing process 1050 described in connection with FIG. 10, as well as alternative model testing processes) to evaluate the accuracy of the machine-learning model 170. To test the accuracy of the machine-learning model 170, the model testing component 166 may compare select outputs of the machine-learning model with other reconstructions (e.g., to periodically test model accuracy). The model testing component 166 can be utilized to determine the overall accuracy of the reconstructed images generated by the machine-learning model 170. In some implementations, the machine-learning model 170 can be provided to the controller 106 (or another computing system that executes the machine-learning model 170) once the machine-learning model 170 is determined to satisfy an accuracy threshold.

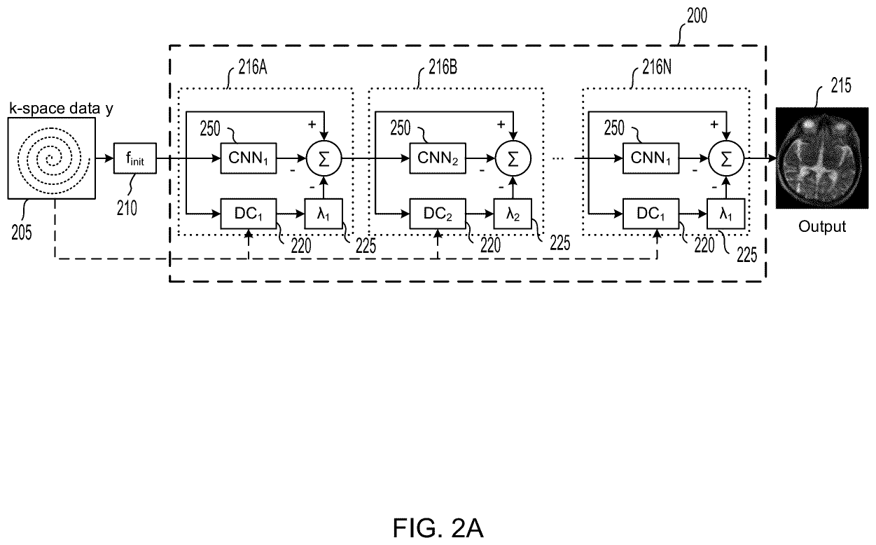

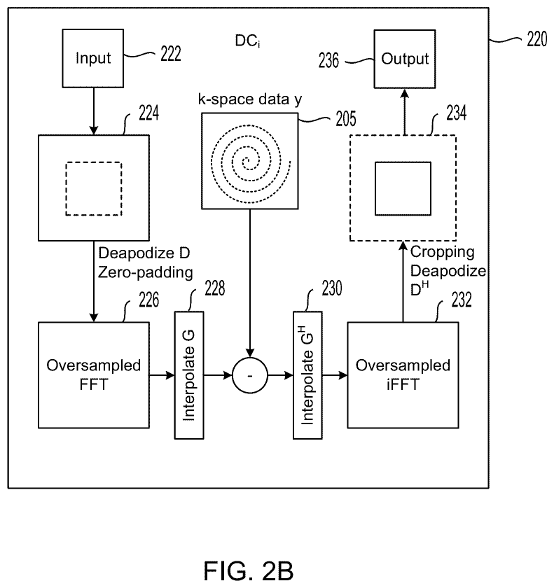

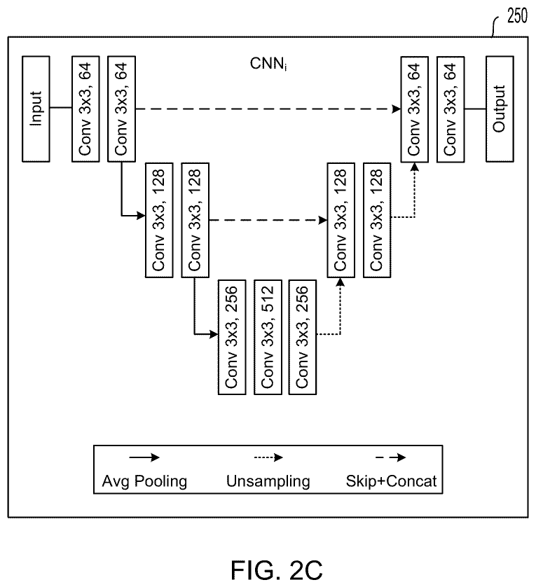

FIG. 2A illustrates a block diagram of an example architecture of a machine-learning model 200 (which may be implemented as the machine-learning model 170 of FIG. 1B, the reconstruction model 306 of FIG. 3, or the reconstruction model 1006 of FIG. 10) for generating MR images from input MR spatial frequency data, in accordance with one or more implementations. As shown in FIG. 2A, the machine-learning model 200 generates the output MR image 215 from input MR spatial frequency data 205 by processing the input MR spatial frequency data 205 in stages. First, the input MR spatial frequency data 205 is processed using initializer block 210, which is then processed by a series of machine-learning blocks 216A, 216B, . . . , 216N (sometimes referred to herein as the “machine-learning block 216” or the “machine-learning blocks 216”).

In some implementations, one or more of the blocks 216A, 216B, . . . , 216N may operate in the image-based domain, and in some implementations, one or more of the blocks 216A, 216B, . . . , 216N may transform the input data to a different domain, including but not limited to the spatial frequency domain, perform processing (e.g., reconstruction processing) in the different domain, and subsequently transform back to the image-based domain. The initializer block 210 can transform the input MR spatial frequency data 205 for subsequent processing by the machine-learning model 200. The initializer block 210 may be implemented in any suitable way. For example, in some embodiments, the initializer block 210 may apply the adjoint non-uniform Fourier transformation to the input MR spatial frequency data to obtain the initial image. The adjoint operator may be implanted, for example, with an oversampling factor of two. As another example, in some embodiments, the initializer block 210 may apply gridding reconstruction to the input MR spatial frequency data 205.

Each machine-learning block 216 can include a data consistency block 220 and a convolutional neural network block 250 each of which can be applied to the respective input of the machine-learning block 216. The input can be the MR image reconstruction generated by the machine-learning model 200 at the completion of the previous block 216. As shown, the output each block 216 can be generated by applying the data consistency block 220 to the input to obtain a first result, applying the convolutional neural network block 250 to the input to obtain a second result, and subtracting from the input a linear combination of the first result and the second result, where the linear combination is calculated using the block-specific weight 225. The block-specific weight may be a learnable parameter of the machine-learning model 200.

The data consistency block 220 may be implemented in any of numerous ways. In some embodiments, the data consistency block 220 may perform data consistency processing by transforming the input image represented by the respective input of the block 216 to the spatial frequency domain using a non-uniform Fourier transformation, comparing the result with the input MR spatial frequency data 205, and transforming the difference between the two back into the image-based domain using an adjoint of the non-uniform Fourier transformation.

FIG. 2B depicts a diagram of an example architecture of a data consistency block 220, which may be part of the example architecture shown in FIG. 2A, in accordance with one or more implementations. As shown in FIG. 2B, the image-based domain input 222 (which may be the intermediate reconstruction input from a previous block 216), is transformed to the spatial frequency domain through a series of three transformations 224, 226, and 228, whose composition can be used to implement a non-Cartesian fast Fourier transformation from the image-based domain to the spatial frequency domain. In this example, the transformation 224 is a deapodization and zero-padding transformation D, the transformation 226 is an oversampled FFT transformation, and the transformation 228 is the gridding interpolation transformation G. After the image-based domain input 222 is transformed to the spatial frequency domain, it is compared with the input MR spatial frequency data 205, and the difference between the two is transformed back to the image-based domain using the transformations 230, 232, and 234. The transformation 230 is the adjoint of the gridding interpolation transformation 228. The transformation 232 is the adjoint of the oversampled FFT transformation 226. The transformation 234 is the adjoint of the deapodization transformation 224. In this way, the composition of the transformations 230, 232, 234, which may be written as represents the adjoint preceding transformations.

FIG. 2C depicts a diagram of an example architecture of a convolutional neural network block 250, which may be part of the example architecture shown in FIG. 2A, in accordance with one or more implementations. The convolutional neural network block 250 may be implemented in any of numerous ways. In some implementations, the convolutional neural network block 250 may have multiple convolutional layers, including one or more convolutional layers and one or more transpose convolutional layers. In some implementations, the convolutional neural network block 250 may have a U-net structure, in which multiple convolutional layers down-sample the data and subsequent transpose convolutional layers up-sample the data, for example, as shown in the illustrative architecture of FIG. 2C. Although FIG. 2C shows that a convolutional neural network can be utilized as part of the machine-learning model 200 of FIG. 2A, it should be understood that additional or alternative models may also be utilized. For example, in some implementations the block 250 can be a neural network, a transformer network with one or more attention layers, or a neural network with one or more Gaussian sampling layers (e.g., a diffusion denoting auto-encoder model).

As shown in FIG. 2C, input to the convolutional neural network block 250 is processing by a down-sampling path followed an up-sampling path. In the down-sampling path, the input is processed by repeated application of two convolutions with 3×3 kernels, each followed by application of a non-linearity (e.g., a rectified linear unit or ReLU), an average 2×2 pooling operation with stride 2 for down-sampling. At each down-sampling step, the number of feature channels is doubled from 64 to 128 to 256. In the up-sampling path, the data is processed be repeated up-sampling of the feature map using an average un-pooling step that halves the number of feature channels, a concatenation with the corresponding feature map from the down-sampling path, and two 3×3 convolutions, each followed by application of a non-linearity (e.g., a ReLU).

FIG. 3 depicts an example dataflow diagram of a dual-domain self-supervised learning process that may be utilized to train a machine-learning model to generate reconstructed MR images, in accordance with one or more implementations. FIG. 3 shows both a training process 300 and a testing process 350. In the training process 300, the input k-space data y (referred to as input k-space data 302) is randomly partitioned into disjoint sets y_{p1,2} (referred to as the partitions 304A and 304B, respectively) and fed into the reconstruction model 306 to produce x_{p1,2} (referred to as the reconstructed images 308A and 308C, respectively, with the reconstruction of the input k-space data 302 being referred to as the reconstructed image 308B) and y_{pred1,2} (referred to as the predicted partitions 312A and 312B, respectively) in image and k-space domains. The reconstruction model 306 is trained under dual-domain losses [symbol] _{PDC}_{_{1,2}} and [symbol] _{AC}_{_{1,2}} calculated from these outputs. In the testing process 350, the trained reconstruction model 306 can directly reconstruct the image from y, which may be compared known faithfully reconstructed images to evaluate the overall accuracy of the reconstruction model 306.

The reconstruction model 306 can be utilized as the machine-learning model 170 described in connection with FIG. 1B. Before discussing the DDSS training process for the reconstruction model 306, it may be helpful to explain the derivation of the approach to reconstruction model 306 for image reconstruction. The derivation of the reconstruction model 306 for use in MR image reconstruction is as follows. The problem to be solved is the construction of a complex two-dimensional (2D) image. Thus, Let x ∈ [symbol] ^{N} be a complex-valued 2D image to be reconstructed, where x is a vector with size of N=NₓN_{y} and Nₓ and N_{y} are the height and width of the image. Given an under-sampled k-space measurement y ∈ [symbol] ^{M} (M<<N), the goal is to reconstruct x from y by solving the unconstrained optimization problem represented in Equation 1 below.

$${arg min}_{x} \frac{λ}{2} {‖ Ax - y ‖}_{2}^{2} + R ( x ) \qquad ( 1 )$$

In Equation 1, A is a non-uniform Fourier sampling operator and R is a regularization term on reconstruction. If data is acquired under uniform or Cartesian sampling patterns, then A=MF, where M is a sampling mask with the same size as A and F is the discrete Fourier transform. However, if data is acquired under a non-Cartesian and non-Cartesian sampling pattern, the k-space measurement locations will no longer located on a uniform k-space grid, thus a generalized definition of A can be given by the non-uniform discrete Fourier transform, represented in Equation 2 below.

$$y ( ( {k}_{x} , {k}_{y} ) ) = {\sum }_{w = 0}^{{N}_{x}} {\sum }_{h = 0}^{{N}_{y}} {x}_{wh} {e}^{2 π i ( \frac{w}{{N}_{x}} {k}_{x} + \frac{h}{{N}_{y}} {k}_{y} )} \qquad ( 2 )$$

In Equation 2, note that (kₓ, k_{y})∈ [symbol] , in contrast to (kₓ, k_{y})∈ [symbol] under Cartesian sampling. [symbol] Using the non-uniform Fast Fourier Transform (NUFFT), Equation 2 can be approximated by Equation 3 below.

$$A = {GF}_{s} D \qquad ( 3 )$$

In Equation 3, G is a gridding interpolation kernel, F_{S} is the fast Fourier Transform (FFT) with an oversampling factor of s, and D is the de-apodization weights. The inversion of A under fully sampled cases can be approximated by gridding reconstruction, which is provided in Equation 4 below.

$$x = {A}^{H} Wy \qquad ( 4 )$$

In Equation 4, W is a diagonal matrix for the density compensation of non-Cartesian measurements. However, when under-sampled, this inversion is ill-posed, thus requiring one to solve Equation 1.

A variational neural network (such as the machine-learning model 200 described in connection with FIGS. 2A, 2B, and 2C), or alternative types of neural networks or machine-learning models, can be used to approximate the solution to the optimization in Equation 1. However, it should be understood that alternative machine-learning models may also be utilized, including neural networks, convolutional neural networks, convolutional neural network in which intermediate layers may be or include data consistency layers, transformer models or other neural networks with attention mechanisms, generative adversarial neural networks, and denoising diffusion probabilistic model or other neural networks with a sequence of layers that model a Gaussian distribution from noise space to input image space, among others. The structure of the variational network is described herein above in connection with FIGS. 2A, 2B, and 2C. The variational network is an unrolled network used to approximate gradient descent on Equation 1. An example backbone network is shown in the convolutional neural network block 250 of FIG. 2C and the data consistency operation is shown in the data consistency block 220 of FIG. 2B. By training using a gradient descent algorithm, a locally optimal solution to Equation 1 can be iteratively computed as Equation 5 below.

$${x}_{i} = {x}_{i - 1} - {α}_{i} {▽}_{x} f ( x ) {\vert}_{x = {x}_{i - 1}} \qquad ( 5 )$$

Equation 5 can have an initial solution that is represented in Equation 6 below.

$${x}_{i} = {f}_{init} ( A , y ) \qquad ( 6 )$$

In Equation 6, ƒᵢₙᵢₜ is an initialization function (e.g., representing operations of the initializer block 210 of FIG. 2A) that is set as ƒᵢₙᵢₜ(A, y)=A^{H}. The gradient of the objective function is represented in Equation 7 below. In Equation 7 below, aᵢ is the gradient descent step size and |ƒ is the gradient of the objective function.

$${∇}_{x} f ( x ) = λ {A}^{H} ( A x - y ) + {∇}_{x} R ( x ) \qquad ( 7 )$$

The sequential update steps are unrolled and formulated as a deep learning-based feed-forward model, in which the regularization gradient term ∇ₓR (x) is approximated by a neural network. In the reconstruction model 306, a 3-level U-Net (e.g., the 3-level U-Net of the convolutional neural network block 250 of FIG. 2C) is used to approximate the regularization gradient term ∇ₓR(x). Thus, the reconstruction model 306 includes an end-to-end trainable variational network with Nᵢₜₑᵣ blocks, as represented in Equation 8 below.

$${x}_{i} = {x}_{i - 1} - {λ}_{i} {A}^{H} ( A {x}_{i - 1} - y ) + {f}_{cnn} ( {x}_{i - 1} \vert {θ}_{i} ) \qquad ( 8 )$$

In Equation 8, θ and λ are learnable parameters. The second term is the data consistency term and the third term is the CNN term.

The reconstruction model 306 is trained using the following dual-domain self-supervised learning techniques, which include the calculation of loss values in both the image-based domain and the frequency domain. Let ƒᵥₙ(A, y) denote the variational network presented in the previous section, where A is the non-uniform Fourier sampling operator and y is the under-sampled k-space measurement. In the DDSS training process 300, the k-space data 302 is partitioned into two disjoint sets, as represented in Equation 9.

$${y}_{p 1} = S ( y , {p}_{1} ) , {y}_{p 2} = S ( y , {p}_{2} ) . \qquad ( 9 )$$

In Equation 9, S is a sampling function with sampling locations p₁ and P₂. The sampling locations may be randomly selected by the computing system performing the training process 300, such that each generated partition is disjoint. Some example sampling functions include a random uniform sampling function, a Gaussian sampling function with a higher probability for the center of the k-space data 302, or any other suitable sampling function. The partitioned data yₚ₁ and yₚ₂ (i.e., the partitions 304A and 304B) are then provided as input to the reconstruction model 306 for parallel reconstruction (with shared weights and other parameters). Execution of the reconstruction model 306 using the partitions 304A and 304B as input generates the reconstructed images 308A and 308C (i.e., xₚ₁ and xₚ₂, respectively), as represented below in Equation 10 below.

$${x}_{p 1} = {f}_{vn} ( {A}_{{y}_{p 1}} , {y}_{p 1} ) \\ {x}_{p 2} = {f}_{vn} ( {A}_{{y}_{p 2}} , {y}_{p 2} ) \qquad ( 10 )$$

The first loss value corresponds to a Partition Data Consistency (PDC) loss, which operates in k-space. If the reconstruction model 306 can generate a high-quality image from any under-sampled k-space measurements, the k-space data of the image predicted from the first partitioned data yₚ₁ should be consistent with the other partition yₚ₂, and vice versa. The first loss value (e.g., the PDC loss value) is calculated to train the model to produce consistent data accordingly. As shown in FIG. 3, the predicted partitions 312A and 312B can be generated by performing a sampling function (e.g., the same sampling function used to generate the partitions 304A and 304B, respectively) on the transformations 310A and 310B of the reconstructed images 308A and 308C, respectively. The transformations 310A and 310B can be calculated from the reconstructed images 308A and 308B using a NUFFT transformation. The predicted partitions 312A and 312B can be represented as Axₚ₁ and Axₚ₂, respectively. As each of the reconstructed images 308A and 308B includes additional information generated by the reconstruction model 306, the other partition can be utilized as a self-supervised comparison for the transformation of each image. For example, when the reconstruction model 306 is properly trained, the first predicted partition 312A should closely resemble the second partition 304B, and the second predicted partition 312B should closely resemble the first partition 304A. The predicted k-space partitions 312A and 312B can be represented in equation form as Equation 11, below.

$${y}_{{pred}_{1}} = S ( A {x}_{p 2} , {p}_{1} ) \\ {y}_{{pred}_{2}} = S ( A {x}_{p 1} , {p}_{2} ) \qquad ( 11 )$$

The PDC loss value can be generated according to Equation 12, below.

$${ℒ}_{PDC} = {‖ {y}_{{pred}_{1}} - {y}_{p 1} ‖}_{1} + {‖ {y}_{{pred}_{2}} - {y}_{p 2} ‖}_{1} \qquad ( 12 )$$

In Equation 12, the first and second terms may correspond to the data consistency losses for the partitions 304A and 304B, respectively.

The reconstruction model 306 can be trained based on a second loss value. The second loss value can be an Appearance Consistency (AC) loss, which can operate in the image-based domain. To calculate the AC loss, in addition to generating outputs corresponding to the first and second partitions 304A and 304B (e.g., yₚ₁ and yₚ₂, respectively), the k-space data 302 in its entirety can also be provided as input to the reconstruction model to generate a third reconstructed image 308B. The generation of the third reconstructed image 308B is represented in Equation 13, below.

$$x = {f}_{vn} ( A , y ) \qquad ( 13 )$$

The reconstruction from under-sampled data y should be consistent with the reconstruction from the partitions yₚ₁ and yₚ₂, respectively. The AC loss value nay be computed on both image intensities and image gradients for improved anatomical clarity between the first reconstructed image 308A and the third reconstructed image 308B, and the second reconstructed image 308C and the third reconstructed image 308B. The AC loss is represented in Equation 14 below.

$${ℒ}_{AC} = {λ}_{img} {ℒ}_{img} + {λ}_{grad} {ℒ}_{grad} \qquad ( 14 )$$

In Equation 14, [symbol] _{img} and [symbol] _{grad} are represented in Equation 15 and Equation 16, respectively, below.

$${ℒ}_{img} = {‖ x - {x}_{p 1} ‖}_{1} + {‖ x - {x}_{p 2} ‖}_{1} \qquad ( 15 )$$

$${ℒ}_{grad} = {‖ {∇}_{v} x - {∇}_{v} {x}_{p 1} ‖}_{1} + {‖ {∇}_{h} x - {∇}_{h} {x}_{p 1} ‖}_{1} + {‖ {∇}_{v} x - {∇}_{v} {x}_{p 2} ‖}_{1} + {‖ {∇}_{h} x - {∇}_{h} {x}_{p 2} ‖}_{1} \qquad ( 16 )$$

In Equations 14, 15, and 16, ∇ᵥ and ∇ₕ are spatial intensity gradient operators in x and y directions, respectively. Example values for λ_{img} and λ_{grad}=1 can include λ_{img}=2 and λ_{grad}=1.

A combination of the PDC loss in k-space and the AC loss in the image-based domain provides a total loss value, which is used to train the reconstruction model 306. The total loss value is represented in Equation 17, below.

$${ℒ}_{tot} = {ℒ}_{AC} + {λ}_{PDC} {ℒ}_{PDC} \qquad ( 17 )$$

In Equation 17, an example value of λ_{PDC}=100 can be used to balance the scale between k-space and image-based domain losses.

The aforementioned training process can be performed using sets training data that include under-sampled and non-Cartesian MR spatial frequency data. As described herein, the above training process 300 does not require the use of previously generated fully reconstructed images to train the model, and instead utilizes a fully self-supervised process in both the image-based domain and the k-space domain to reconstruct MR images. The training process 300 can be performed iteratively on sets of training data that include k-space spatial frequency data 302. Various batch sizes and numbers of epochs can be used to train the model (e.g., a batch size of 8 with 200 epochs, etc.). The testing process 350 can be performed to evaluate the performance of the reconstruction model 306 during or after training. To do so, input k-space data 302 may be provided as input, and the reconstruction model 306 can be executed to produce the reconstructed image 314.

Evaluating the performance of the reconstruction model 306 can include comparing the reconstructed image 314 to a known faithfully reconstructed image for the input k-space data 302 to determine the similarity between the reconstructed image 314 and the expected output of the reconstruction model 306. The degree of similarity between the reconstructed image 314 and the expected output can be proportional to the accuracy of the model. The reconstruction model 306 can be evaluated using a test set of k-space data 302 for which faithful reconstructions are available to calculate and average (mean) accuracy for the model. The testing process 350 may be performed, for example, after predetermined amounts of training data (e.g., batches, epochs, etc.) have been used to train the model, to iteratively determine the accuracy of the model. When the accuracy of the model reaches a predetermined threshold, or when a predetermined training termination condition is met (e.g., a set amount of training data has been used to train the reconstruction model 306, such as a predetermined number of epochs).

FIG. 4 illustrates a flowchart of an example method 400 of training a machine-learning model (e.g., the machine-learning model 170, the machine-learning model 200, the reconstruction model 306, etc.) to generate reconstructed MR images using dual-domain self-supervised learning techniques, in accordance with one or more implementations. The method 400 may be executed using any suitable computing system (e.g., the training platform 160, the controller 106, or the computing device 104 of FIG. 1, the computing system 1700 of FIG. 17, etc.). It will be appreciated that certain steps of the method 400 may be executed in parallel (e.g., concurrently) or sequentially, while still achieving desired results. The method 400 can be executed iteratively to update or otherwise train the machine-learning model.

The method 400 can include act 405, in which obtained MR spatial frequency data is partitioned into first and second partitions, as described herein. The input MR spatial frequency data can be obtained for use as training data to train the machine-learning model. The input MR spatial frequency data can be data that was previously obtained by an MRI system and stored for subsequent analysis. In some implementations, the input MR spatial frequency data may be obtained by an MRI system (including any of the MRI systems described herein) as part of the method 400. The MR spatial frequency data can be non-Cartesian spatial frequency data (e.g., obtained using a non-Cartesian sampling trajectory). The MR spatial frequency data can be non-Cartesian. The partitions can be generated using any suitable sampling function. Some example sampling functions include a random uniform sampling function, a Gaussian sampling function (e.g., with a higher probability for the center of the input MR spatial frequency data), or any other suitable sampling function.

The method 400 can include act 410, in which the first partition, the second partition, and the MR spatial frequency data are each provided as inputs to the machine-learning model, which is executed to generate respective reconstructed images (e.g., reconstructed images 308A, 308B, and 308C) for each input. Generating an output can include providing the respective input to an initializer block, and subsequently providing the output of the initializer block as input to the machine-learning model, as described herein. The outputs of the machine-learning model can include propagating the input data through one or more blocks or layers of the machine-learning model, as described herein. The same weight values or other parameters values for the machine-learning model can be used for each input.

To execute the machine-learning model, the input data can be propagated through one or more data consistency blocks, which may include a NUFFT and comparison with the initial MR spatial frequency provided as input to the model, as described herein. In addition, the input data can be propagated through one or more convolutional neural network blocks, as described herein. This can include applying multiple sets of convolutional filters to a copy of the input data. The results of the data consistency block and the convolutional neural network block can combined in a linear combination. This output can then be provided to as input to the next block of the machine-learning model, or as the reconstructed image if all blocks in the machine-learning model have been applied.

The method 400 can include act 415, in which an AC loss value is calculated based on the outputs of the machine-learning model. As described herein, the AC loss corresponds to the image-based domain, and can indicate a visual similarity between the outputs of the machine-learning model produced using each partition and the output of the machine-learning model produced using the input MR spatial frequency data. The AC loss can be calculated, for example, using Equations 14, 15, and 16 as described herein. The AC loss value can be computed on both image intensities and image gradients to encourage improved anatomical clarity between the outputs, as described herein. The AC loss value can be utilized to train the machine-learning model in combination with one or more other losses, as described in further detail below. It will be appreciated that the first loss can be or may include alternative loss functions, including L1 loss, L2 loss, gradient loss, histogram of oriented gradients (HOG) loss, or contrastive loss, among others.

The method 400 can include act 420, in which the outputs of the machine-learning model generated from the partitions (e.g., the reconstructed images 308A and 308C) are transformed into the frequency domain, prior to calculating a second loss value. To do so, an NUFFT process can be applied to the outputs generated from the partitions, to generate corresponding transformations (e.g., the transformations 310A and 310B). The transformations can then be used in subsequent steps of the method 400 to calculate the second loss, which can correspond to the frequency domain.

The method 400 can include act 425, in which a data consistency loss (e.g., the PDC loss) is calculated based on the partitions generated in act 405 and the transformations generated in act 420. As described herein, each of the outputs of the machine-learning model includes additional information generated by the machine-learning model. As such, the other partition (e.g., the partition other than the one used to generate the respective output) can be used as a self-supervised comparison value for each output in the frequency domain. This can be represented as the PDC loss, which can be calculated using Equation 12 as described herein. Calculating the PDC loss can include partitioning the transformations generated in act 420 using the same sampling function used to generate the partitions in act 405. Alternative or additional loss functions may be calculated for the frequency domain, including weighted data consistency loss, L1 loss, L2 loss, Lₚ loss, or masked loss, among others.

The method 400 can include act 430, in which the machine-learning model can be trained and updated based on the loss values calculated in acts 415 and 425. For example, the machine-learning model can be trained based on the total loss value represented in Equation 17, as described herein. Training the machine-learning model can include updating the weights or other trainable parameters of the machine-learning model using any suitable training techniques, such as stochastic gradient descent and back-propagation. Once the weights or trainable parameters of the machine-learning model have been updated according to the total loss, the method 400 can return to act 405 to perform the method 400 using different input training data. The method 400 can be repeated iteratively until desired model performance (e.g., accuracy), or when a predetermined training termination condition is met (e.g., a set amount of training data has been used to train the reconstruction model 306, such as a predetermined number of epochs). In some implementations, the accuracy of the machine-learning model can be periodically evaluated using a testing process.

The DDSS techniques described above were evaluated according to various example criteria to show various improvements over other implementations. Example experimental data follows that evaluates an example implementation on both simulated and real non-Cartesian data. For the simulation studies, 505 T1-weighted and 125 T2-weighted 3D brain MR images were randomly selected from the Human Connectome Project (HCP) with no subject overlap. The volumes were first resampled to 1.5×1.5×5 mm³ to match common clinical resolutions. A two-dimensional non-Cartesian multi-coil data acquisition protocol was utilized, where eight coil sensitivity maps were analytically generated. To generate non-Cartesian under-sampled data, a variable density sampling pattern was used, where the sampling density decays from the k-space center at a quadratic rate. Two sampling trajectory settings were generated with target acceleration factor R ∈ {2,4}. T1-weighted and 104 T2-weighted images are used for training and 29 T1-weighted and 21 T2-weighted MR images for evaluation.

For the real-world MRI studies, 106 FLAIR and 112 FSE-T2w 3D brain MR images were acquired using a portable MRI system (e.g., a HYPERFINE SWOOP system manufactured by Hyperfine, Inc.) with a field strength of about 64 mT. Both FLAIR and FSE-T2w images were acquired using a variable density sampling pattern with an acceleration factor of two. The resolution was 1.6×1.6×5 mm³.

The example machine-learning models used to produce the data in Table 1 were optimized with Adam Optimizer, with the following parameters: lr=3×10⁻⁵,β¹=0.9, and β₂=0.999. A batch size of eight was used, and the machine-learning models were trained for 200 epochs. The default number of iterations in the non-Cartesian reconstruction network was set to six. During training, the under-sampled data partitioning rate is randomly generated between [0.2, 0.8].

As an upper bound, the DDSS was compared against a supervised strategy where the same reconstruction model was trained in a fully supervised fashion. As ablations, results from an adjoint-only model are presented, and to further evaluate the advantages of dual-domain training, a comparison is drawn against a k-space domain self-supervised model where only the k-space domain PDC loss is used for reconstruction model training.

For quantification on the simulated non-Cartesian HCP data, the structural similarity index (SSIM), peak signal-to-noise ratio (PSNR), and mean squared error (MSE) are measured. For evaluations using real clinical data, the real non-Cartesian data is used for self-supervised training and is qualitatively evaluated, as there are no faithful reconstructions for quantification. Some example results are provided in Table 1 below.

TABLE 1
below provides a quantitative comparison of image reconstruction under two different
non-Cartesian signal acquisition settings using SSIM, SNR, and MSE (MSE are scaled by 10³).

| | Evaluation | | | | | |
|---|---|---|---|---|---|---|
| | Setting 1 (R = 2) | | | Setting 2 (R = 4) | | |
| | SSIM | PSNR | MSE | SSIM | PSNR | MSE |
| T1w | | | | | | |
| Adjoint | 0.714(0.092) | 21.125(3.577) | 0.186(0.255) | 0.482(0.093) | 16.569(3.180) | 0.479(0.518) |
| KDSS | 0.925(0.019) | 32.149(2.347) | 0.012(0.011) | 0.897(0.033) | 29.892(3.657) | 0.026(0.046) |
| DDSS (Ours) | 0.943(0.007) | 32.957(2.801) | 0.011(0.013) | 0.901(0.034) | 31.381(3.582) | 0.020(0.042) |
| Supervised | 0.981(0.014) | 38.666(4.302) | 0.004(0.001) | 0.948(0.028) | 36.423(3.982) | 0.012(0.009) |
| (Upper Bound) | | | | | | |
| T2w | | | | | | |
| Adjoint | 0.731(0.072) | 21.325(3.208) | 0.157(0.136) | 0.498(0.073) | 17.197(2.973) | 0.391(0.310) |
| KDSS | 0.926(0.018) | 32.135(1.805) | 0.011(0.005) | 0.904(0.019) | 29.879(2.943) | 0.021(0.016) |
| DDSS (Ours) | 0.945(0.007) | 32.955(2.255) | 0.009(0.005) | 0.907(0.018) | 31.354(2.957) | 0.015(0.012) |
| Supervised | 0.983(0.011) | 38.712(3.702) | 0.003(0.003) | 0.951(0.026) | 36.511(3.668) | 0.011(0.008) |
| (Upper Bound) | | | | | | |

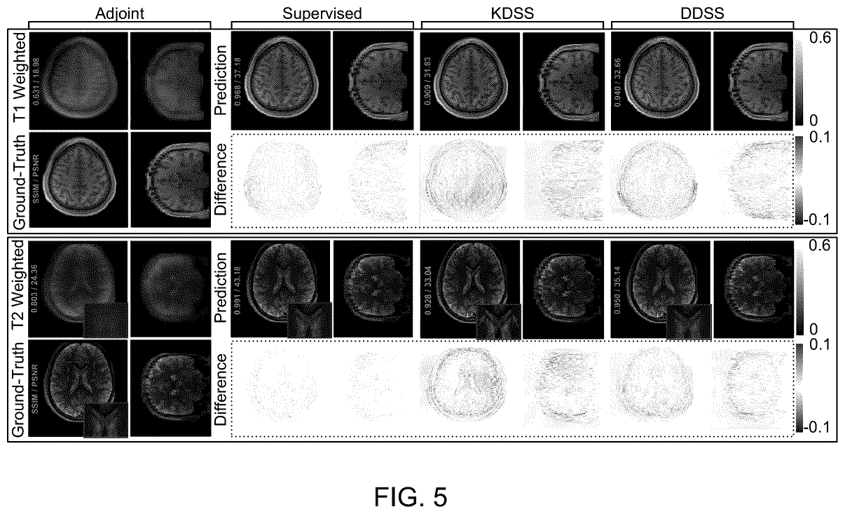

As shown in Table 1, with acceleration R=2 on T1w reconstruction, DDSS can achieve SSIM=0.943 which is notably higher than the KDSS with SSIM=0.925, thus narrowing the gap in performance to the fully supervised upper bound. Similar observations can be found for T2w reconstruction experiments where the DDSS outperforms the KDSS by achieving the SSIM of 0.945 over the KDSS with 0.926. While the over-all performance decreases for all methods as the acceleration factor increases from R=2 to R=4, DDSS still outperforms KDSS on both T1w and T2w reconstruction tasks in terms of PSNR, SSIM and MSE. Qualitative comparisons are visualized in FIG. 5.

FIG. 5 depicts visualizations of example non-Cartesian MRI reconstructions using supervised, KDSS, and dual-domain self-supervised approaches, in accordance with one or more implementations. In FIG. 5, both T1-weighted results (top) and T2-weighted results (bottom) are shown along with their respective error maps. In KDSS, overestimation can be observed for important anatomical structures. As compared to single-domain self-supervised learning (e.g., KDSS), the DDSS reconstructions resulted in lower over-all errors for both T1w and T2w reconstructions. Even though the supervised model using fully sampled data during training achieves the best quantitative results, the reconstructions from the supervised model and the DDSS are comparable qualitatively.

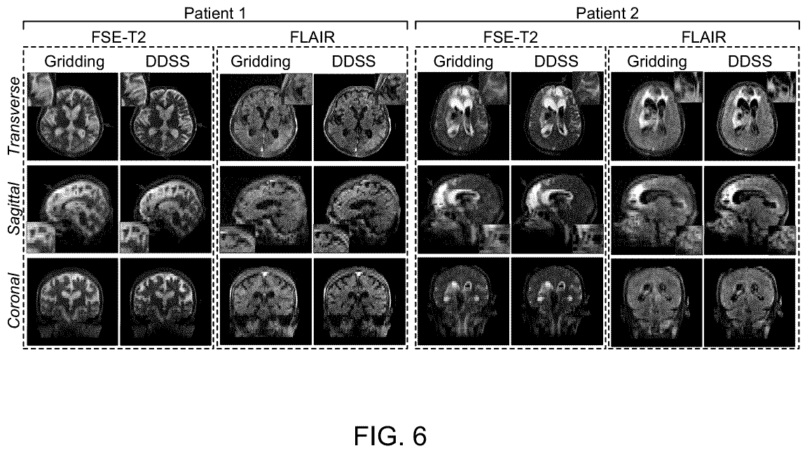

As described herein, portable, bedside, low cost, and low-field MRI can contribute valuable information for brain disease diagnosis in clinical settings. Unlike conventional MRI with uniform sampling patterns, the data acquired from the low-field MRI scanner is non-Cartesian with acceleration R=2. Thus, the DDSS approaches can be evaluated on the low-field MRI data acquired by such systems. To do so, a machine-learning model was trained using the DDSS techniques described herein with such data. Performance of the machine-learning model was compared against the default gridding reconstruction from the system. Qualitative results are visualized in FIG. 6.

FIG. 6 depicts visualizations of a qualitative evaluation of FSE-T2w and FLAIR reconstructions from data acquired from a low-field (64 mT) MRI system, in accordance with one or more implementations. In FIG. 6, gridding reconstructions are compared against the DDSS reconstructions for two stroke patients. Patient 1 suffered from a hemorrhagic stroke with lacunar infarcts. Patient 2 suffered from a hemorrhagic stroke with midline shift. Notably, the gridding reconstructions suffer from blurring due to the accelerated data acquisition protocols, while the self-supervised DDSS reconstructions produce much sharper image quality leading to enhanced visualization of neuroanatomy.

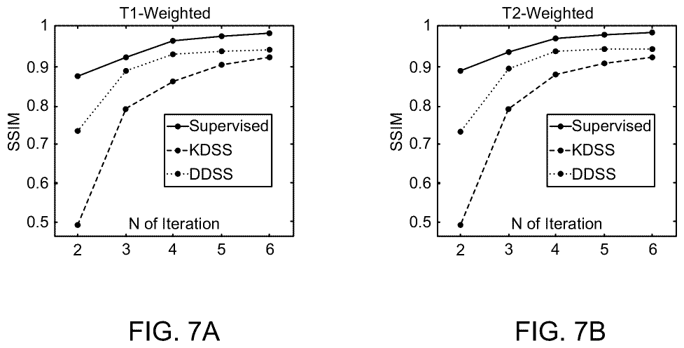

FIGS. 7A and 7B depict the impact of the number of iterations in the non-Cartesian reconstruction network for DDSS reconstruction, in accordance with one or more implementations. As shown, the DDSS consistently outperforms the KDSS at different numbers of iterations, and achieved closer performance to the fully supervised models. For the DDSS techniques described herein, the reconstruction performance starts to asymptotically converge after four iterations. Experiments on T1w and T2w reconstructions show similar behavior.

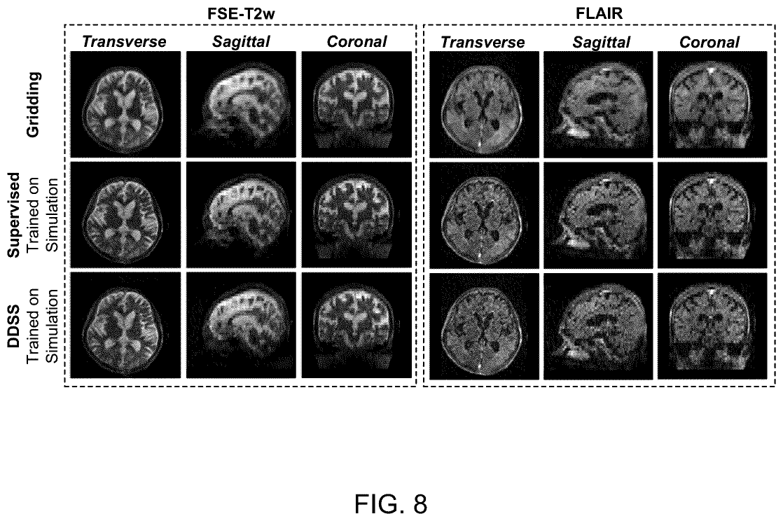

To qualitatively evaluate the gap between the DDSS and the fully supervised trained model in terms of real data, both the fully supervised model trained on simulation data and the DDSS trained on simulation data (with only under-sampled data) were applied to real data. Qualitative results are summarized in FIG. 8.

FIG. 8 depicts visualizations of MR image reconstructions of FSE-T2w and FLAIR using fully supervised model and DDSS model trained on simulation data, in accordance with one or more implementations. Results for the fully supervised model are shown in the second row, and results for the model trained using the DDSS techniques described herein are shown in the third row. As shown in FIG. 8, applying the models trained on simulation data to real data also can produce sharper image quality as compared to the gridding reconstructions. The reconstructions from the fully supervised model and the DDSS are remarkably visually consistent, indicating the model trained in fully supervised fashion and model trained in the DDSS fashion could provide similar performance on real data.

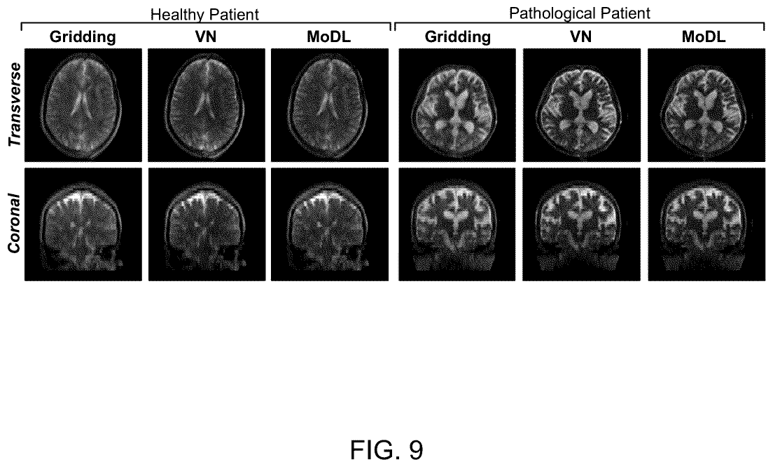

Moreover, the DDSS is a flexible framework, where the backbone reconstruction model is interchangeable and is not limited to the example variational network described herein. As an ablation study, an alternative deep-learning architecture (MoDL) was trained using the DDSS techniques described herein to qualitatively evaluate the reconstruction on real data. The results are visualized in FIG. 9, with examples of one healthy patient and one pathological patient.

FIG. 9 depicts a visualization of a qualitative comparison of the present DDSS techniques with an alternative backbone reconstruction network approach (in this example, MoDL), in accordance with one or more implementations. In FIG. 9, FSE-T2w is used, and both pathological and healthy patient examples are visualized. The number of cascades in the MoDL model is set to four. As shown, the DDSS with MoDL can also produce sharper image quality as compared to the gridding reconstructions. Visually speaking, the reconstructions from the example model proposed herein (e.g., the machine-learning model 200) trained using the DDSS techniques and the MoDL-based DDSS are consistent to a great extent, which means that the DDSS can integrate with different backbone non-Cartesian reconstruction networks while producing reasonable reconstructions.

In summary, some advantages of the techniques described herein include a training process for a non-Cartesian MRI reconstruction network in both image and k-space domains in a self-supervised fashion. At least two major challenges were overcome. First, the present techniques enable training the machine-learning models without using any fully sampled MRI data, instead of relying on large-scale under- and fully-sampled paired data for the training process, which is infeasible if the MRI system has accelerated acquisition protocols. Second, the techniques described herein can be utilized for non-Cartesian MRI reconstruction, rather than uniform MRI reconstruction. These approaches are therefore suitable for MRI systems with non-Cartesian acquisition protocols and without fully sampled data.

It will be appreciated that variations of the aforementioned techniques are further contemplated, including the following example modifications and the alternative training process 1000 described in connection with FIG. 10. In the examples described herein, the non-Cartesian reconstruction model is based on gradient descent where the data consistency constraint could be further enforced. However, utilizing a conjugate gradient-based architecture may improve performance. Additionally, the image and k-space self-supervisions of the DDSS as described herein are the final output of the non-Cartesian reconstruction model. However, deep supervision on each cascade output can be implemented to potentially improve performance. Alternatives to the U-Net architecture as the backbone network described herein may be utilized, as the particular model architectures used in connection with the DDSS techniques described herein are interchangeable. For example, an MPR architecture, an RDN architecture, or an OUCNet architecture could be utilized. Additionally, the present techniques can be extended from 2D framework to 3D to potentially increase the reconstruction performance.

FIG. 10 depicts an example dataflow diagram of an alternative dual-domain self-supervised training process 1000 that may be utilized to train a machine-learning model (e.g., the machine-learning model 170, the machine-learning model 200, the reconstruction model 1006, etc.) to generate reconstructed MR images, in accordance with one or more implementations.

The training process 1000 begins by randomly partitioning the input k-space data 1002 into disjoint sets y_{p1,2} (referred to as the partitions 1004A and 1004B, respectively) and fed into the reconstruction model 1006 (which is similar to the various reconstruction models described herein) to produce x_{p1,2} (referred to as the reconstructed images 1008A and 1008C, respectively, with the reconstruction of the input k-space data 1002 being referred to as the reconstructed image 1008B). The training process 1000 differs from the training process 300 in that different losses are used to train the reconstruction model 1006. The input k-space data can be partitioned using suitable sampling functions, as described herein.

Representations of the reconstructed images 1008A, 1008B, and 1008C, which correspond to the first partition 1004A, the input k-space data 1002, and the second partition 1004B, respectively, are represented in Equations 18, 19, and 20, respectively, below.

$${x}_{{p}_{1}} = {f}_{vn} ( {A}_{{y}_{p 1}} , {y}_{{p}_{1}} ) \qquad ( 18 )$$

$${x}_{{p}_{2}} = {f}_{vn} ( {A}_{{y}_{p 2}} , {y}_{{p}_{2}} ) \qquad ( 19 )$$

$${x}_{u} = {f}_{vn} ( A , y ) \qquad ( 20 )$$

The dual domain loss functions are calculated based on these outputs as follows. The AC loss in the training process 1000 is calculated based on Equation 14 (described herein above). However, the terms [symbol] _{img} and [symbol] _{grad} are different, and are represented in Equations 21 and 22, below.

$${ℒ}_{img} = {‖ x - {x}_{{p}_{1}} ‖}_{1} + {‖ x - {x}_{{p}_{2}} ‖}_{1} + {‖ {x}_{{p}_{1}} - {x}_{{p}_{2}} ‖}_{1} \qquad ( 21 )$$

$$\begin{matrix}{ℒ}_{grad} = {‖ {∇}_{v} {x}_{u} - {∇}_{v} {x}_{{p}_{1}} ‖}_{1} + {‖ {∇}_{h} {x}_{u} - {∇}_{h} {x}_{{p}_{1}} ‖}_{1} , \\ + {‖ {∇}_{v} {x}_{u} - {∇}_{v} {x}_{{p}_{2}} ‖}_{1} + {‖ {∇}_{h} {x}_{u} - {∇}_{h} {x}_{{p}_{2}} ‖}_{1} , \\ + {‖ {∇}_{v} {x}_{{p}_{1}} - {∇}_{v} {x}_{{p}_{2}} ‖}_{1} + {‖ {∇}_{h} {x}_{{p}_{1}} - {∇}_{h} {x}_{{p}_{2}} ‖}_{1}\end{matrix} \qquad ( 22 )$$

In Equations 21 and 22, ∇ᵥ and vₕ are spatial intensity gradient operators in x and y directions, respectively. In Equations 21 and 22, rather than only considering the difference between the outputs 1008A and 1008C and the reconstruction 1008B of the input data, the [symbol] _{img} and [symbol] _{grad} terms also include additional terms for the consistency between the outputs 1008A and 1008C (e.g., the outputs generated from the partitions). This additional term encourages the reconstruction model 1006 to generate images that are consistent from the disjoint partitions.

In addition to a modified AC loss value, the training process 1000 also calculates a different PDC loss to train the reconstruction model 1006. Rather than generating a transformation (e.g., using NUFFT) of only the outputs generated from the partitions 1004A and 1004B, an additional transformation of the output data xᵤ (e.g., generated by the reconstruction model 1006 using the k-space data 1002 as input) is calculated. Each of these transformations (e.g., the transformations 101A, 1010B, and 100C) are represented by Equations 23, 24, and 25, below.

$${y}_{{pred}_{1}} = A {x}_{{p}_{1}} \qquad ( 23 )$$

$${y}_{{pred}_{2}} = A {x}_{{p}_{2}} \qquad ( 24 )$$

$${y}_{{pred}_{u}} = A {x}_{{p}_{u}} \qquad ( 25 )$$

The PDC loss is then calculated directed from the transformations 101A, 1010B, and 101C, and from the input k-space data 1002, rather than sampling the transformations and calculating the PDC loss using the input partitions. In this approach, the frequency domain outputs of the reconstruction model 1006 are encouraged to be consistent with the initial input k-space data 1002. This alternative PDC loss can be calculated according to Equation 26 below.

$${ℒ}_{PDC} = {‖ {y}_{{pred}_{1}} - y ‖}_{1} + {‖ {y}_{{pred}_{2}} - y ‖}_{1} + {‖ {y}_{{pred}_{u}} - y ‖}_{1} \qquad ( 26 )$$

The alternative training process 1000 can be performed using sets training data that include under-sampled and non-Cartesian MR spatial frequency data, without requiring the use of fully sampled data to train the reconstruction model 1006. The training process 1000 is therefore fully self-supervised in both the frequency and image-based domains. The training process 1000 can be performed iteratively on sets of training data that include k-space spatial frequency data 1002. The testing process 1050 can be performed to evaluate the performance of the reconstruction model 1006 during or after training. To do so, input k-space data 1002 can be provided as input, and the reconstruction model 306 can be executed to produce the reconstructed image 1014, which may be evaluated against suitable reconstructions of the input data.

FIG. 11 illustrates a flowchart of an example method 400 of training a machine-learning model (e.g., the machine-learning model 170, the machine-learning model 200, the reconstruction model 1006, etc.) to generate reconstructed MR images using the alternative dual-domain self-supervised learning techniques described in connection with FIG. 10, in accordance with one or more implementations. The method 1100 may be executed using any suitable computing system (e.g., the training platform 160, the controller 106, or the computing device 104 of FIG. 1, the computing system 1700 of FIG. 17, etc.). It will be appreciated that certain steps of the method 1100 may be executed in parallel (e.g., concurrently) or sequentially, while still achieving desired results. The method 1100 can be executed iteratively to update or otherwise train the machine-learning model.

The method 1100 can include act 1105, in which obtained MR spatial frequency data is partitioned into first and second partitions, as described herein. The input MR spatial frequency data can be obtained for use as training data to train the machine-learning model. The input MR spatial frequency data can be data that was previously obtained by an MRI system and stored for subsequent analysis. In some implementations, the input MR spatial frequency data may be obtained by an MRI system (including any of the MRI systems described herein) as part of the method 1100. The MR spatial frequency data can be non-Cartesian spatial frequency data (e.g., obtained using a non-Cartesian sampling trajectory). The MR spatial frequency data can be non-Cartesian. The partitions can be generated using any suitable sampling function. Some example sampling functions include a random uniform sampling function, a Gaussian sampling function (e.g., with a higher probability for the center of the input MR spatial frequency data), or any other suitable sampling function.

The method 1100 can include act 1110, in which the first partition, the second partition, and the MR spatial frequency data are each provided as inputs to the machine-learning model, which is executed to generate respective reconstructed images (e.g., reconstructed images 1008A, 1008B, and 1008C) for each input. Generating an output can include providing the respective input to an initializer block (e.g., the initializer block 210, as described in connection with FIG. 2A), and subsequently providing the output of the initializer block as input to the machine-learning model (e.g., as shown in FIG. 2A). The outputs of the machine-learning model can include propagating the input data through one or more blocks (e.g., the blocks 216 of FIG. 2A) of the machine-learning model, as described in connection with FIGS. 2A, 2B, and 2C. The same weight values or other parameters values for the machine-learning model can be used for each input.

The method 1100 can include act 1115, in which an AC loss value is calculated based on the outputs (e.g., the reconstructed images 1008A, 1008B, or 1008C of FIG. 10) of the machine-learning model. The alternative AC loss can be calculated using similar to those described in connection with FIG. 10. The AC loss corresponds to the image-based domain. The AC loss can be calculated, for example, using Equations 21, 22, and 16 as described herein. The AC loss value can be computed on both image intensities and image gradients to encourage improved anatomical clarity between the outputs, as described herein. The AC loss value can be utilized to train the machine-learning model in combination with one or more other losses, such as the alternative PDC loss, as described in further detail herein. Additional loss values may be calculated to encourage consistency in the image-based domain, including but not limited to L1 loss, L2 loss, gradient loss, histogram of oriented gradients (HOG) loss, or contrastive loss, among others.

The method 1100 can include act 1120, in which the outputs of the machine-learning model generated from the partitions and the input MR spatial frequency data (e.g., the reconstructed images 1008A, 1008B, and 1008C) are transformed into the frequency domain, prior to calculating the PDC loss value. To do so, an NUFFT process can be applied to the outputs generated from the machine-learning model, to generate corresponding transformations (e.g., the transformations 1010A, 1010B, and 1010C). The transformations can then be used in subsequent steps of the method 1100 to calculate the PDF loss, which can correspond to the frequency domain.

The method 1100 can include act 1125, in which a data consistency loss (e.g., the PDC loss) is calculated based on the input MR spatial frequency data and each of the transformations generated in act 1120. This alternative PDC loss can be calculated using Equation 26. Calculating the PDC loss in this manner encourages consistency between the outputs generated by the machine-learning model and the input MR spatial frequency data. Alternative or additional loss functions may also be calculated to ensure consistency in the frequency domain, including weighted data consistency loss, L1 loss, L2 loss, Lₚ loss, or masked loss, among others.

The method 1100 can include act 1130, in which the machine-learning model can be trained and updated based on the loss values calculated in acts 1115 and 1125. To do so alternative AC loss and PDC loss values can be calculated. For example, the machine-learning model can be trained based on the total loss value represented in Equation 17, using the alternative AC loss and PDC loss values described in connection with FIG. 10. Training the machine-learning model can include updating the weights or other trainable parameters of the machine-learning model using any suitable training techniques, such as stochastic gradient descent and back-propagation. Once the weights or trainable parameters of the machine-learning model have been updated according to the total loss, the method 1100 can return to step 1105 to perform the method 1100 using different input training data. As described herein, the method 1100 can be iteratively repeated until a predetermined training condition has been met (e.g., a predetermined amount of training data has been utilized, a predetermined accuracy has been achieved, etc.).

The DDSS techniques that utilize the alternative losses described in connection with FIG. 10 were evaluated according the same example criteria described herein above. As above, for the simulation studies, 505 T1-weighted and 125 T2-weighted 3D brain MR images were randomly selected from the HCP with no subject overlap. The volumes were first resampled to 1.5×1.5×5 mm³ to match common clinical resolutions. A two-dimensional non-Cartesian multi-coil data acquisition protocol was utilized, where eight coil sensitivity maps were analytically generated. To generate non-Cartesian under-sampled data, a variable density sampling pattern was used, where the sampling density decays from the k-space center at a quadratic rate. Two sampling trajectory settings were generated with target acceleration factor R ∈ {2,4}. T1-weighted and 104 T2-weighted images are used for training and 29 T1-weighted and 21 T2-weighted MR images for evaluation. Also as described above, the same approaches are used for the real-world MRI image evaluation for the DDSS techniques implementing the losses described in connection with FIG. 10. In particular, 106 FLAIR and 112 FSE-T2w 3D brain MR images were acquired using a portable MRI system with a field strength of 64 mT. Both FLAIR and FSE-T2w images were acquired using a variable density sampling pattern with an acceleration factor of two. The resolution was 1.6×1.6×5 mm³.

TABLE 2
below provides a quantitative comparison of image reconstruction under two different
non-Cartesian signal acquisition settings using SSIM, SNR, and NMSE.

| | Evaluation | | | | | |
|---|---|---|---|---|---|---|
| | Setting 1 (R = 2) | | | Setting 2 (R = 4) | | |
| | SSIM | PSNR | NMSE | SSIM | PSNR | NMSE |
| T1w | | | | | | |
| Adjoint | 0.810 ± 0.057 | 15.881 ± 4.150 | 0.848 ± 0.663 | 0.762 ± 0.071 | 14.584 ± 4.192 | 1.174 ± 0.934 |
| Gridding/SDC | 0.886 ± 0.032 | 19.941 ± 3.767 | 0.295 ± 0.145 | 0.818 ± 0.057 | 16.859 ± 4.097 | 0.675 ± 0.555 |
| CG-SENSE | 0.921 ± 0.021 | 22.641 ± 3.230 | 0.151 ± 0.049 | 0.880 ± 0.034 | 19.997 ± 3.450 | 0.291 ± 0.148 |
| L1-Wavelet | 0.927 ± 0.018 | 23.106 ± 3.091 | 0.134 ± 0.037 | 0.893 ± 0.028 | 20.787 ± 3.280 | 0.238 ± 0.109 |
| SSDU | 0.960 ± 0.021 | 26.301 ± 1.253 | 0.073 ± 0.041 | 0.898 ± 0.033 | 23.370 ± 2.911 | 0.123 ± 0.019 |
| KDSS | 0.981 ± 0.004 | 30.454 ± 2.447 | 0.024 ± 0.005 | 0.941 ± 0.022 | 26.303 ± 3.169 | 0.063 ± 0.011 |
| DDSS (Ours) | 0.988 ± 0.006^{†} | 33.678 ± 3.926^{†} | 0.012 ± 0.005^{†} | 0.947 ± 0.022^{†} | 27.223 ± 3.353^{†} | 0.051 ± 0.013^{†} |
| Supervised | 0.996 ± 0.002 | 39.080 ± 4.336 | 0.003 ± 0.002 | 0.954 ± 0.020 | 27.760 ± 3.349 | 0.046 ± 0.013 |
| (Upper Bound) | | | | | | |
| T2w | | | | | | |
| Adjoint | 0.795 ± 0.033 | 15.909 ± 2.307 | 0.883 ± 0.356 | 0.745 ± 0.042 | 14.735 ± 2.322 | 1.184 ± 0.526 |
| Gridding/SDC | 0.866 ± 0.027 | 19.170 ± 2.556 | 0.402 ± 0.128 | 0.800 ± 0.042 | 16.712 ± 2.741 | 0.743 ± 0.303 |
| CG-SENSE | 0.908 ± 0.019 | 22.398 ± 2.454 | 0.183 ± 0.035 | 0.860 ± 0.032 | 19.550 ± 2.833 | 0.368 ± 0.121 |
| L1-Wavelet | 0.914 ± 0.017 | 22.889 ± 2.403 | 0.163 ± 0.030 | 0.874 ± 0.028 | 20.190 ± 2.750 | 0.314 ± 0.095 |
| SSDU | 0.950 ± 0.021 | 26.030 ± 1.577 | 0.089 ± 0.041 | 0.900 ± 0.023 | 23.458 ± 2.552 | 0.142 ± 0.015 |
| KDSS | 0.980 ± 0.003 | 30.490 ± 2.071 | 0.028 ± 0.006 | 0.944 ± 0.017 | 26.513 ± 2.866 | 0.071 ± 0.011 |
| DDSS (Ours) | 0.988 ± 0.004^{†} | 33.739 ± 3.324^{†} | 0.013 ± 0.003^{†} | 0.949 ± 0.015^{†} | 27.213 ± 2.900^{†} | 0.060 ± 0.009^{†} |
| Supervised | 0.996 ± 0.002 | 39.102 ± 3.743 | 0.004 ± 0.002 | 0.953 ± 0.013 | 27.544 ± 2.909 | 0.057 ± 0.011 |
| (Upper Bound) | | | | | | |

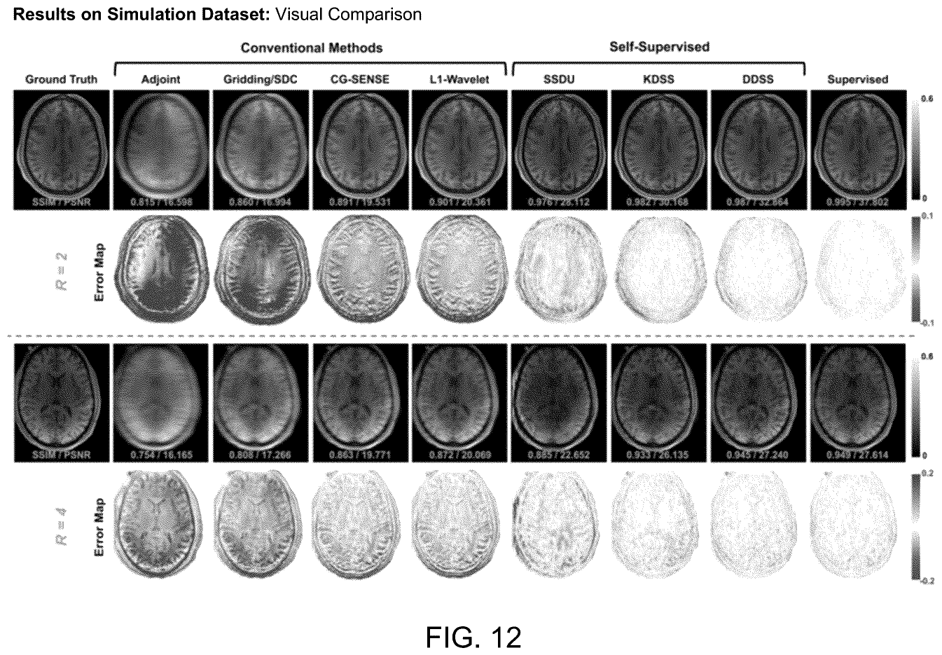

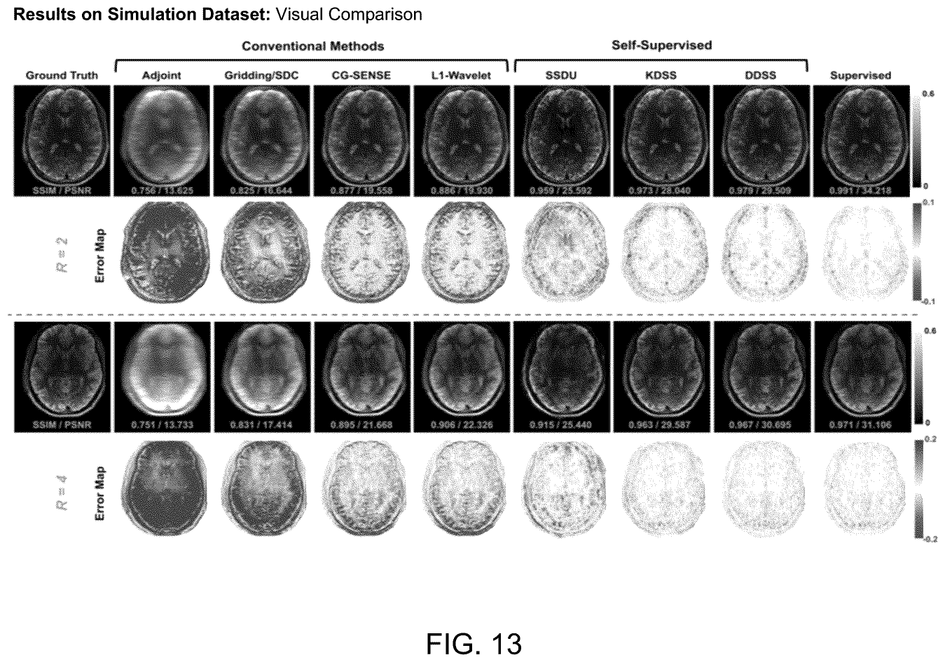

Visualizations reflecting experiments on simulated data conducted using the DDSS techniques described herein with the alternative losses described in connection with FIG. 10 are shown in FIGS. 12 and 13. FIG. 12 illustrates an example visual comparison of MR image reconstruction using conventional methods and the alternative dual-domain self-supervised techniques described herein with a simulation dataset, in accordance with one or more implementations. As shown in FIG. 12, the reconstructed images produced by the DDSS techniques implementing the alternative losses of FIG. 10 are compared to both conventional methods and alternative self-supervised approaches. Based on these visualizations, it is clear that the DDSS results in overall less visual consistency error than both conventional methods and other self-supervised methods (e.g., SSDU and KDSS), with accuracy approaching a fully supervised approach. Similar results are shown in FIG. 13, which illustrates another example visual comparison of MR image reconstruction using conventional methods and the dual-domain self-supervised techniques with the alternative losses of FIG. 10, as described herein.

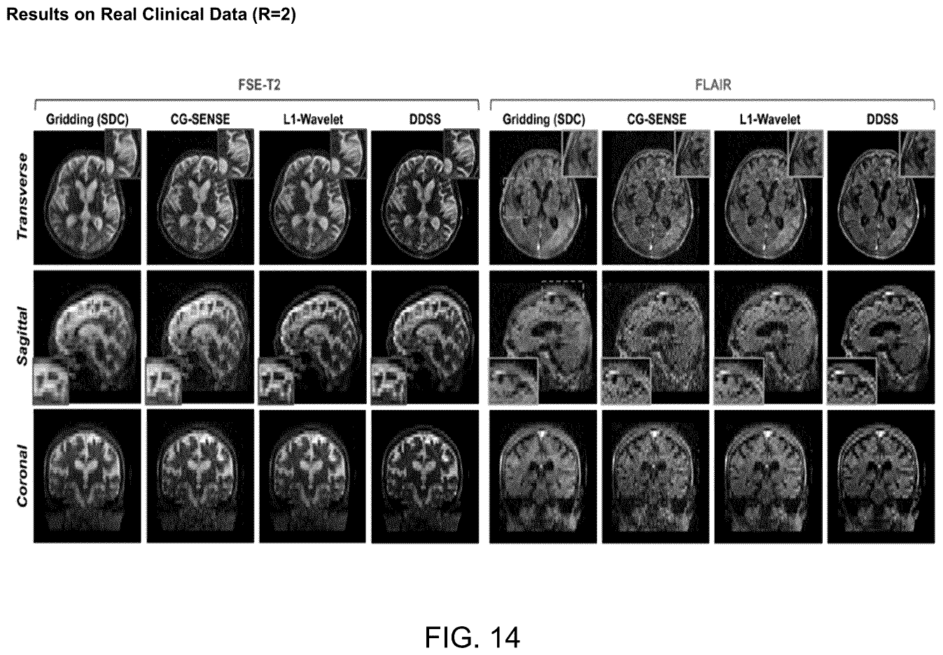

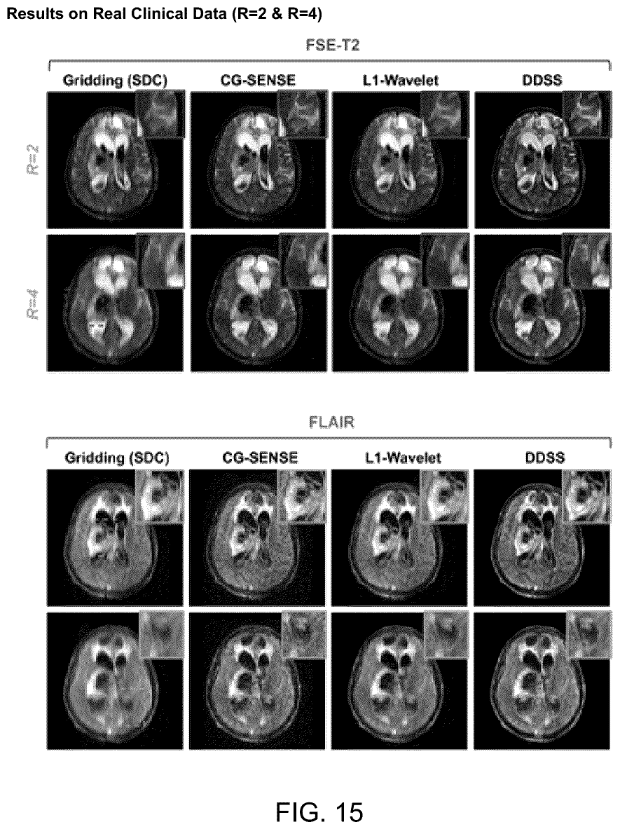

Visualizations reflecting experiments on real clinical data conducted using the DDSS techniques described herein with the alternative losses described in connection with FIG. 10 are shown in FIGS. 14 and 15. FIG. 14 illustrates visualizations of FSE-T2 and FLAIR reconstructions from real clinical data, in accordance with one or more implementations. As shown, the DDSS techniques utilizing the alternative losses result in improved visual clarify when compared to other approaches such as Gridding, CG-SENSE, and L1-Wavelet, for both the FSE-T2 and FLAIR. Similar results are also shown in FIG. 15, which illustrates additional visualizations of FSE-T2 and FLAIR reconstructions from real clinical data using the DDSS approaches described herein compared to alternative approaches.

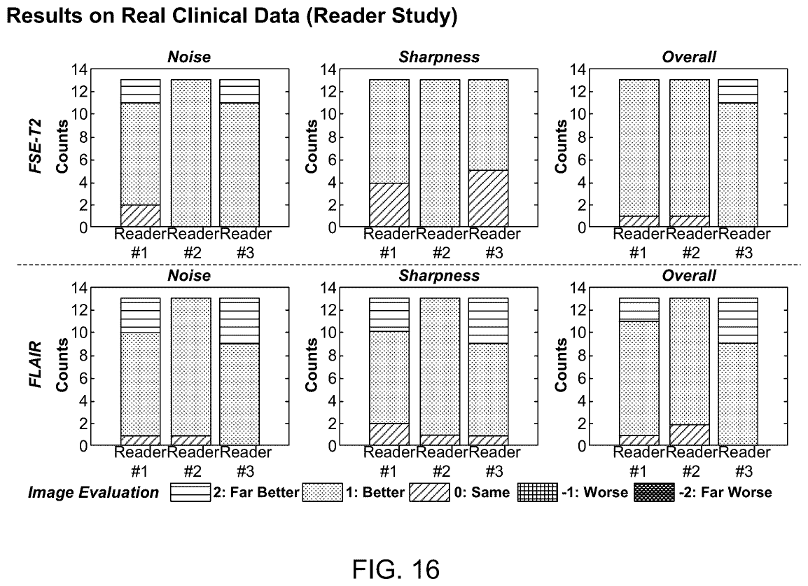

FIG. 16 illustrates graphs indicating results of a reader study performed on reconstructions generated using the techniques described herein and alternative approaches. The reader study was performed using the reconstructions of real clinical data. As shown by the graphs of FIG. 16, the DDSS approaches described herein result in markedly better sharpness, noise levels, and overall quality than alternative reconstruction approaches.

In summary, the systems and methods of this technical solution provide several approaches for dual-domain self-supervised learning that enables training a non-Cartesian MRI reconstruction deep model without using any fully sampled data. Self-supervision is utilized in both the k-space and image-based domains, which is shown to lead to improved MR image reconstructions. The experimental results on a non-Cartesian dataset described herein demonstrate that the DDSS can generate highly accurate reconstructions that approach the fidelity of the fully supervised reconstruction, but without requiring fully sampled or fully uniform data. Additionally, the machine-learning models trained using the DDSS techniques described herein can be used to reconstruct challenging real MRI data from a portable low-field MRI scanner, where fully sampled data is unavailable.

FIG. 17 is a component diagram of an example computing system suitable for use in the various implementations described herein, according to an example implementation. For example, the computing system 1700 may implement a computing device 104 or controller 106 of FIG. 1, or various other example systems and devices described in the present disclosure.

The computing system 1700 includes a bus 1702 or other communication component for communicating information and a processor 1704 coupled to the bus 1702 for processing information. The computing system 1700 also includes main memory 1706, such as a RAM or other dynamic storage device, coupled to the bus 1702 for storing information, and instructions to be executed by the processor 1704. Main memory 1706 can also be used for storing position information, temporary variables, or other intermediate information during execution of instructions by the processor 1704. The computing system 1700 may further include a ROM 1708 or other static storage device coupled to the bus 1702 for storing static information and instructions for the processor 1704. A storage device 1710, such as a solid-state device, magnetic disk, or optical disk, is coupled to the bus 1702 for persistently storing information and instructions.

The computing system 1700 may be coupled via the bus 1702 to a display 1714, such as a liquid crystal display, or active matrix display, for displaying information to a user. An input device 1712, such as a keyboard including alphanumeric and other keys, may be coupled to the bus 1702 for communicating information, and command selections to the processor 1704. In another implementation, the input device 1712 has a touch screen display. The input device 1712 can include any type of biometric sensor, or a cursor control, such as a mouse, a trackball, or cursor direction keys, for communicating direction information and command selections to the processor 1704 and for controlling cursor movement on the display 1714.

In some implementations, the computing system 1700 may include a communications adapter 1716, such as a networking adapter. Communications adapter 1716 may be coupled to bus 1702 and may be configured to enable communications with a computing or communications network or other computing systems. In various illustrative implementations, any type of networking configuration may be achieved using communications adapter 1716, such as wired (e.g., via Ethernet), wireless (e.g., via Wi-Fi, Bluetooth), satellite (e.g., via GPS) pre-configured, ad-hoc, LAN, WAN, and the like.

According to various implementations, the processes of the illustrative implementations that are described herein can be achieved by the computing system 1700 in response to the processor 1704 executing an implementation of instructions contained in main memory 1706. Such instructions can be read into main memory 1706 from another computer-readable medium, such as the storage device 1710. Execution of the implementation of instructions contained in main memory 1706 causes the computing system 1700 to perform the illustrative processes described herein. One or more processors in a multi-processing implementation may also be employed to execute the instructions contained in main memory 1706. In alternative implementations, hard-wired circuitry may be used in place of or in combination with software instructions to implement illustrative implementations. Thus, implementations are not limited to any specific combination of hardware circuitry and software.

Potential embodiments include, without limitation:

Embodiment AA: A method comprising training, by one or more processors coupled to a non-transitory memory, a machine-learning model that receives magnetic resonance (MR) data and generates a reconstruction of the MR data, the machine-learning model trained based on a set of losses comprising a first loss value corresponding to a frequency-domain and a second loss value corresponding to an image-based domain.

Embodiment AB: The method of Embodiment AA, wherein the set of losses comprises a partition data consistency (PDC) loss operating in the frequency domain of training data, and an appearance consistency (AC) loss operating in the image-based domain of the training data.

Embodiment AC: The method of either Embodiment AA or Embodiment AB, wherein the set of losses comprises an AC loss, wherein the AC loss is computed based on image densities and image gradients.

Embodiment AD: The method of any of Embodiments AA-AC, wherein the machine-learning model is trained based on two subsets of training MR data, each subset generated by applying a sampling function to a set of locations of the training data.

Embodiment AE: The method of any of Embodiments AA-AD, wherein the machine-learning model is trained based on two subsets of training MR data, wherein the two subsets are disjoint sets.

Embodiment AF: The method of any of Embodiments AA-AE, wherein the machine-learning model is trained by feeding two subsets of training MR data into a variational network to obtain two predicted subsets.

Embodiment AG: The method of any of Embodiments AA-AF, wherein at least one of the losses in the set of losses is based on two subsets of training MR data and two predicted subsets.

Embodiment AH: The method of any of Embodiments AA-AG, wherein the MR data is MR spatial frequency data captured using an MR system.

Embodiment AI: The method of any of Embodiments AA-AH, wherein the MR spatial frequency data is non-Cartesian.

Embodiment AJ: The method of any of Embodiments AA-AI, wherein the reconstruction of the MR data comprises a representation of the MR data in the image-based domain.

Embodiment AK: The method of any of Embodiments AA-AJ, wherein the machine-learning model is a generative adversarial network (GAN) model.

Embodiment AL: The method of any of Embodiments AA-AK, wherein the first loss value is calculated based on (1) a first output of the machine-learning model generated using a first subset of input MR data, and (2) a second output of the machine-learning model generated using the input MR data.

Embodiment AM: The method of Embodiment AL, wherein the first loss value is calculated further based on a third output of the machine-learning model generated using a second subset of the input MR data.

Embodiment AN: The method of either Embodiment AL or Embodiment AM, wherein the second loss value is calculated based on a subset of a transformation of the first output and a corresponding second subset of the input MR data.

Embodiment AO: The method of Embodiment AN, wherein the second loss value is calculated further based on (1) a second transformation of a third output of the machine-learning model generated using the corresponding second subset of the input MR data, and (2) the first subset of the input MR data.

Embodiment AP: The method of any of Embodiments AL-AO, wherein the second loss value is calculated based on a transformation of the first output and the input MR data.

Embodiment AQ: The method of any of Embodiments AA-AP, wherein the machine-learning model comprises a plurality of convolutional layers and a plurality of data consistency layers.

Embodiment AR: The method of Embodiment AQ, wherein the plurality of convolutional layers and the plurality of data consistency layers are arranged in a plurality of blocks, such that each of the plurality of blocks comprises at least one convolutional layer and at least one data consistency layer.

Embodiment AS: The method of any of Embodiments AA-AR, wherein the machine-learning model is a dual-domain self-supervised model.

Embodiment AT: The method of any of Embodiments AA-AS, wherein the machine-learning model is self-supervised in both k-space and image-based domains.

Embodiment AU: The method of any of Embodiments AA-AT, wherein the machine-learning model is a self-supervised model for reconstruction of non-Cartesian MRI data.

Embodiment AV: The method of any of Embodiments AA-AU, further comprising receiving patient MR data and feeding the patient MR data to the machine-learning model to obtain a reconstructed image based on the patient MR data.

Embodiment AW: The method of Embodiment AV, wherein the MR patient data is captured using a low-field MRI scanner.

Embodiment BA: A method, comprising: training, by one or more processors coupled to a non-transitory memory, based on a first loss value and a second loss value, a machine-learning model that generates magnetic resonance (MR) images from MR spatial frequency data, wherein training the machine-learning model comprises: calculating, by the one or more processors, the first loss value based on a first output of the machine-learning model generated using a first partition of input MR spatial frequency data and a second output of the machine-learning model generated using the input MR spatial frequency data; and calculating, by the one or more processors, the second loss value based on (1) the input MR spatial frequency data and a transformation of the first output of the machine-learning model, or (2) a partition of the transformation of the first output and a second partition of the input MR spatial frequency data.

Embodiment BB: The method of Embodiment BA, further comprising: generating, by the one or more processors, the first partition of the input MR spatial frequency data by selecting a first subset of the input MR spatial frequency data; and generating, by the one or more processors, the second partition of the input MR spatial frequency data by selecting a second subset of the input MR spatial frequency data.

Embodiment BC: The method of either Embodiment BA or BB, wherein the first partition and the second partition are generated using a sampling function.

Embodiment BD: The method of any of Embodiments BA-BC, wherein the partition of the transformation of the first output is generated using the sampling function of the second partition of the input MR spatial frequency data.

Embodiment BE: The method of any of Embodiments BA-BD, wherein the first partition of the input MR spatial frequency data and the second partition of the input MR spatial frequency data are disjoint sets.

Embodiment BF: The method of any of Embodiments BA-BE, wherein calculating the first loss value is further based on a third output of the machine-learning model generated using the second partition of the input MR spatial frequency data.

Embodiment BG: The method of any of Embodiments BA-BF, wherein calculating the second loss value is further based on a transformation of a third output of the machine-learning model generated using the second partition of the input MR spatial frequency data.

Embodiment BH: The method of any of Embodiments BA-BG, wherein the machine-learning model is a GAN-based model.

Embodiment BI: The method of any of Embodiments BA-BH, wherein the machine-learning model comprises a plurality of data consistency layers and a plurality of convolutional layers.

Embodiment BJ: The method of Embodiment BI, wherein the plurality of convolutional layers and the plurality of data consistency layers are arranged in a plurality of blocks, such that each of the plurality of blocks comprises at least one convolutional layer and at least one data consistency layer.

Embodiment BK: The method of any of Embodiments BA-BJ, wherein the input MR spatial frequency data comprises under-sampled data.

Embodiment BL: The method of any of Embodiments BA-BK, wherein the input MR spatial frequency data comprises non-Cartesian sampled data.

Embodiment BM: The method of any of Embodiments BA-BL, wherein the machine-learning model is a dual-domain self-supervised model.

Embodiment BN: The method of any of Embodiments BA-BM, wherein the machine-learning model is self-supervised in both k-space and image-based domains.

Embodiment BO: The method of any of Embodiments BA-BN, wherein the machine-learning model is a self-supervised model for reconstruction of non-Cartesian MRI data.

Embodiment BP: The method of any of Embodiments BA-BO, further comprising receiving patient MR data and feeding the patient MR data to the machine-learning model to obtain a reconstructed image based on the patient MR data.

Embodiment BQ: The method of Embodiment BP, wherein the MR patient data is captured using a low-field MRI scanner.

Embodiment CA: A system, comprising: a magnetic resonance (MR) imaging system configured to generate MR spatial frequency data; and one or more processors configured to: cause the MR imaging system to generate the MR spatial frequency data based on a non-Cartesian sampling pattern; and execute a machine-learning model to generate an MR image based on the MR spatial frequency data, the machine-learning model trained based on a first loss value corresponding to a frequency-domain and a second loss value corresponding to an image-based domain.

Embodiment CB: The system of Embodiment CA, wherein the machine-learning model is a GAN-based model.

Embodiment CC: The system of either Embodiment CA or CB, wherein the first loss value is calculated based on (1) a first output of the machine-learning model generated using a first subset of MR training data, and (2) a second output of the machine-learning model generated using the MR training data.

Embodiment CD: The system of Embodiment CC, wherein the first loss value is calculated further based on a third output of the machine-learning model generated using a second subset of the MR training data.

Embodiment CE: The system of either Embodiment CC or CD, wherein the second loss value is calculated based on a subset of a transformation of the first output and a corresponding second subset of the MR training data.

Embodiment CF: The system of Embodiment CE, wherein the second loss value is calculated further based on (1) a second transformation of a third output of the machine-learning model generated using the corresponding second subset of the MR training data, and (2) the first subset of the MR training data.

Embodiment CG: The system of any of Embodiments CC-CF, wherein the second loss value is calculated based on a transformation of the first output and the MR training data.

Embodiment CH: The system of any of Embodiments CA-CG, wherein the machine-learning model comprises a plurality of convolutional layers and a plurality of data consistency layers.

Embodiment CI: The system of Embodiment CH, wherein the plurality of convolutional layers and the plurality of data consistency layers are arranged in a plurality of blocks, such that each of the plurality of blocks comprises at least one convolutional layer and at least one data consistency layer.

Embodiment CJ: The system of any of Embodiments CA-CI, wherein the MR imaging system comprises a low-field MR imaging device.

Embodiment CK: The system of any of Embodiments CA-CJ, wherein the MR imaging system comprises a portable low-field MR imaging device.

The implementations described herein have been described with reference to drawings. The drawings illustrate certain details of specific implementations that implement the systems, methods, and programs described herein. However, describing the implementations with drawings should not be construed as imposing on the disclosure any limitations that may be present in the drawings.

It should be understood that no claim element herein is to be construed under the provisions of 35 U.S.C. § 112(f), unless the element is expressly recited using the phrase “means for.”

As used herein, the term “circuit” may include hardware structured to execute the functions described herein. In some implementations, each respective “circuit” may include machine-readable media for configuring the hardware to execute the functions described herein. The circuit may be embodied as one or more circuitry components including, but not limited to, processing circuitry, network interfaces, peripheral devices, input devices, output devices, sensors, etc. In some implementations, a circuit may take the form of one or more analog circuits, electronic circuits (e.g., integrated circuits (IC), discrete circuits, system on a chip (SOC) circuits), telecommunication circuits, hybrid circuits, and any other type of “circuit.” In this regard, the “circuit” may include any type of component for accomplishing or facilitating achievement of the operations described herein. For example, a circuit as described herein may include one or more transistors, logic gates (e.g., NAND, AND, NOR, OR, XOR, NOT, XNOR), resistors, multiplexers, registers, capacitors, inductors, diodes, wiring, and so on.

The “circuit” may also include one or more processors communicatively coupled to one or more memory or memory devices. In this regard, the one or more processors may execute instructions stored in the memory or may execute instructions otherwise accessible to the one or more processors. In some implementations, the one or more processors may be embodied in various ways. The one or more processors may be constructed in a manner sufficient to perform at least the operations described herein. In some implementations, the one or more processors may be shared by multiple circuits (e.g., circuit A and circuit B may comprise or otherwise share the same processor, which, in some example implementations, may execute instructions stored, or otherwise accessed, via different areas of memory). Alternatively or additionally, the one or more processors may be structured to perform or otherwise execute certain operations independent of one or more co-processors.

In other example implementations, two or more processors may be coupled via a bus to enable independent, parallel, pipelined, or multi-threaded instruction execution. Each processor may be implemented as one or more general-purpose processors, ASICs, FPGAs, GPUs, TPUs, digital signal processors (DSPs), or other suitable electronic data processing components structured to execute instructions provided by memory. The one or more processors may take the form of a single core processor, multi-core processor (e.g., a dual core processor, triple core processor, or quad core processor), microprocessor, etc. In some implementations, the one or more processors may be external to the apparatus, for example, the one or more processors may be a remote processor (e.g., a cloud-based processor). Alternatively or additionally, the one or more processors may be internal or local to the apparatus. In this regard, a given circuit or components thereof may be disposed locally (e.g., as part of a local server, a local computing system) or remotely (e.g., as part of a remote server such as a cloud based server). To that end, a “circuit” as described herein may include components that are distributed across one or more locations.

An exemplary system for implementing the overall system or portions of the implementations might include a general purpose computing devices in the form of computers, including a processing unit, a system memory, and a system bus that couples various system components including the system memory to the processing unit. Each memory device may include non-transient volatile storage media, non-volatile storage media, non-transitory storage media (e.g., one or more volatile or non-volatile memories), etc. In some implementations, the non-volatile media may take the form of ROM, flash memory (e.g., flash memory such as NAND, 3D NAND, NOR, 3D NOR), EEPROM, MRAM, magnetic storage, hard discs, optical discs, etc. In other implementations, the volatile storage media may take the form of RAM, TRAM, ZRAM, etc. Combinations of the above are also included within the scope of machine-readable media. In this regard, machine-executable instructions comprise, for example, instructions and data, which cause a general-purpose computer, special purpose computer, or special purpose processing machines to perform a certain function or group of functions. Each respective memory device may be operable to maintain or otherwise store information relating to the operations performed by one or more associated circuits, including processor instructions and related data (e.g., database components, object code components, script components), in accordance with the example implementations described herein.

It should also be noted that the term “input devices,” as described herein, may include any type of input device including, but not limited to, a keyboard, a keypad, a mouse, joystick, or other input devices performing a similar function. Comparatively, the term “output device,” as described herein, may include any type of output device including, but not limited to, a computer monitor, printer, facsimile machine, or other output devices performing a similar function.

It should be noted that although the diagrams herein may show a specific order and composition of method steps, it is understood that the order of these steps may differ from what is depicted. For example, two or more steps may be performed concurrently or with partial concurrence. Also, some method steps that are performed as discrete steps may be combined, steps being performed as a combined step may be separated into discrete steps, the sequence of certain processes may be reversed or otherwise varied, and the nature or number of discrete processes may be altered or varied. The order or sequence of any element or apparatus may be varied or substituted according to alternative implementations. Accordingly, all such modifications are intended to be included within the scope of the present disclosure as defined in the appended claims. Such variations will depend on the machine-readable media and hardware systems chosen and on designer choice. It is understood that all such variations are within the scope of the disclosure. Likewise, software and web implementations of the present disclosure could be accomplished with standard programming techniques with rule-based logic and other logic to accomplish the various database searching steps, correlation steps, comparison steps, and decision steps.

While this specification contains many specific implementation details, these should not be construed as limitations on the scope of any inventions or of what may be claimed, but rather as descriptions of features specific to particular implementations of the systems and methods described herein. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products.

Having now described some illustrative implementations and implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements, and features discussed only in connection with one implementation are not intended to be excluded from a similar role in other implementations.

The phraseology and terminology used herein is for the purpose of description and should not be regarded as limiting. The use of “including,” “comprising,” “having,” “containing,” “involving,” “characterized by,” “characterized in that,” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act, or element may include implementations where the act or element is based at least in part on any information, act, or element.

Any implementation disclosed herein may be combined with any other implementation, and references to “an implementation,” “some implementations,” “an alternate implementation,” “various implementation,” “one implementation,” or the like are not necessarily mutually exclusive and are intended to indicate that a particular feature, structure, or characteristic described in connection with the implementation may be included in at least one implementation. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms.

Where technical features in the drawings, detailed description or any claim are followed by reference signs, the reference signs have been included for the sole purpose of increasing the intelligibility of the drawings, detailed description, and claims. Accordingly, neither the reference signs nor their absence have any limiting effect on the scope of any claim elements.

The foregoing description of implementations has been presented for purposes of illustration and description. It is not intended to be exhaustive or to limit the disclosure to the precise form disclosed, and modifications and variations are possible in light of the above teachings or may be acquired from this disclosure. The implementations were chosen and described in order to explain the principals of the disclosure and its practical application to enable one skilled in the art to utilize the various implementations and with various modifications as are suited to the particular use contemplated. Other substitutions, modifications, changes, and omissions may be made in the design, operating conditions and implementation of the implementations without departing from the scope of the present disclosure as expressed in the appended claims.

What is claimed is:

1. A method comprising training, by one or more processors coupled to a non-transitory memory, a machine-learning model that receives magnetic resonance (MR) data and generates a reconstruction of the MR data, the machine-learning model trained based on a set of losses comprising a first loss value corresponding to a frequency-domain and a second loss value corresponding to an image-based domain.

2. The method of claim 1, wherein the set of losses comprises a partition data consistency (PDC) loss operating in the frequency domain of training data, and an appearance consistency (AC) loss operating in the image-based domain of the training data.

3. The method of claim 1, wherein the machine-learning model is trained based on two subsets of training MR data, each subset generated by applying a sampling function to a set of locations of the training data.

4. The method of claim 3, wherein the machine-learning model is further trained by feeding the two subsets into a variational network to obtain two predicted subsets, and wherein at least one of the losses in the set of losses is based on the two subsets and the two predicted subsets.

5. The method of claim 1, wherein the MR data is non-Cartesian MR spatial frequency data captured using an MR system.

6. The method of claim 1, wherein the first loss value is calculated based on (1) a first output of the machine-learning model generated using a first subset of input MR data, and (2) a second output of the machine-learning model generated using the input MR data, and wherein the second loss value is calculated based on a subset of a transformation of the first output and a corresponding second subset of the input MR data.

7. The method of claim 1, wherein the machine-learning model is a dual-domain self-supervised model.

8. The method of claim 1, further comprising receiving patient MR data and feeding the patient MR data to the machine-learning model to obtain a reconstructed image based on the patient MR data.

9. A method, comprising:
training, by one or more processors coupled to a non-transitory memory, based on a first loss value and a second loss value, a machine-learning model that generates magnetic resonance (MR) images from MR spatial frequency data, wherein training the machine-learning model comprises:
calculating, by the one or more processors, the first loss value based on a first output of the machine-learning model generated using a first partition of input MR spatial frequency data and a second output of the machine-learning model generated using the input MR spatial frequency data; and
calculating, by the one or more processors, the second loss value based on (1) the input MR spatial frequency data and a transformation of the first output of the machine-learning model, or (2) a partition of the transformation of the first output and a second partition of the input MR spatial frequency data.

10. The method of claim 9, further comprising:
generating, by the one or more processors, the first partition of the input MR spatial frequency data by selecting a first subset of the input MR spatial frequency data; and
generating, by the one or more processors, the second partition of the input MR spatial frequency data by selecting a second subset of the input MR spatial frequency data.

11. The method of claim 9, wherein the machine-learning model comprises a plurality of data consistency layers and a plurality of convolutional layers, and wherein the plurality of convolutional layers and the plurality of data consistency layers are arranged in a plurality of blocks, such that each of the plurality of blocks comprises at least one convolutional layer and at least one data consistency layer.

12. The method of claim 9, wherein the machine-learning model is a dual-domain self-supervised model, wherein the machine-learning model is self-supervised in both k-space and image-based domains, and wherein the machine-learning model is for reconstruction of non-Cartesian MRI data.

13. The method of claim 9, further comprising receiving patient MR data and feeding the patient MR data to the machine-learning model to obtain a reconstructed image based on the patient MR data.

14. A system, comprising:
a magnetic resonance (MR) imaging system configured to generate MR spatial frequency data; and
one or more processors configured to:
cause the MR imaging system to generate the MR spatial frequency data based on a non-Cartesian sampling pattern; and
execute a machine-learning model to generate an MR image based on the MR spatial frequency data, the machine-learning model trained based on a first loss value corresponding to a frequency-domain and a second loss value corresponding to an image-based domain.

15. The system of claim 14, wherein the first loss value is calculated based on (1) a first output of the machine-learning model generated using a first subset of MR training data, and (2) a second output of the machine-learning model generated using the MR training data, and wherein the second loss value is calculated based on a subset of a transformation of the first output and a corresponding second subset of the MR training data.
